(19) United States
(12) Patent Application Publication
(10) Pub. No.: US 2012/0006489 A1
(43) Pub. Date: Jan. 12, 2012

(54) PLASMA PROCESSING APPARATUS AND PLASMA PROCESSING METHOD

(76) Inventors: Shogo Okita, Hyogo (JP); Hiromi Asakura, Hyogo (JP)

(21) Appl. No.: 13/257,636

(22) PCT Filed: Mar. 23, 2010
(86) PCT No.: PCT/JP2010/002035

§ 371 Date: Sep. 20, 2011

(30) Foreign Application Priority Data
Mar. 26, 2009 (JP) 2009-076596
Apr. 13, 2009 (JP) 2009-097251

(51) Int. Cl. H01L 21/3065; C23C 16/50; C23C 16/503

(52) U.S. Cl. 156/345.43; 118/723 R; 118/723 E; 156/345.52

(57) ABSTRACT

Substrates are contained in substrate containing holes which penetrate a tray in the thickness direction. A dielectric plate in a chamber is provided with a tray supporting surface which supports the lower surface of the tray and substrate placing sections which protrude upward, and has an electrostatic chuck electrode therein. The substrate supporting section which supports the substrate contained in the substrate containing holes is provided with a plurality of protruding sections formed at intervals in the circumferential direction of the substrate containing holes. The substrates are supported in point-contact mode by means of the protruding sections.

### BACKGROUND OF THE INVENTION

1. Technical Field

The present invention relates to a plasma processing apparatus such as a dry etching apparatus and a CVD apparatus.

2. Description of the Related Art

Japanese Patent Application Laid-Open Publication 2007-109770 discloses a plasma processing apparatus in which a tray containing a substrate in a substrate containing hole passing through in the thickness direction, the tray capable of being carried in and out, is arranged on a substrate susceptor functioning as a lower part electrode, and the substrate is placed on an upper end surface (substrate placing surface) of a substrate placing section of the substrate susceptor brought into the substrate containing hole. The substrate is closely attached onto the substrate placing surface by electrostatic chuck, and a heat transfer gas is charged between the substrate and the substrate placing surface. A cooling mechanism is provided in the substrate susceptor, and the substrate is cooled by direct heat transfer with the substrate susceptor. After completion of plasma processing, the substrate is brought from the substrate placing surface to the substrate containing hole of the tray, and further, the tray containing the substrate is carried out from a chamber to a load lock chamber. After that, the load lock chamber is purged to atmosphere, and the tray containing the substrate is put from the load lock chamber into a cassette.

During the plasma processing, the substrate is cooled due to the heat transfer with the substrate susceptor as described above, whereas the tray is not effectively cooled, and thus has a high temperature. For example, in order to process the substrate at high speed by dry etching for manufacturing LEDs or the like, there is a need for executing the dry etching under a condition that plasma density is high and bias power is also high. Under this condition, in comparison to the effectively cooled substrate, the tray has a considerably high temperature due to heat absorption from the plasma. After the dry etching and successive carrying-out to the load lock chamber, when an ambience in the load lock chamber is switched from vacuum to the atmosphere, and the load lock chamber is purged to the atmosphere, a temperature of the substrate is remarkably increased due to the heat transfer from the tray having a high temperature. Particularly, in an outer circumferential edge section of the substrate in the vicinity of a hole wall of the substrate containing hole, the temperature is remarkably increased due to the heat transfer from the tray.

This temperature increase of the tray after the plasma processing may cause a decrease in quality and damage of the substrate. When the tray having an increased temperature stands by in the load lock chamber and the tray is cooled by heat release to a vacuum space or heat transfer to a carrying arm for carrying out the tray, there is a need for a stand-by time. Thus, this may cause throughput degradation. A cooling chamber (cooling stage) can be provided adjacent to the chamber, so as to cool the tray after the plasma processing. However, provision of this cooling chamber may cause complication of the apparatus and a cost increase.

An object of the present invention is to reduce a temperature increase of a substrate due to heat transfer from a tray after completion of plasma processing in a plasma processing apparatus in which the tray containing the substrate in a substrate containing hole is arranged on a substrate susceptor.

A first aspect of the present invention is to provide a plasma processing apparatus, including a chamber capable of being decompressed, a plasma generation source for generating plasma in the chamber, a tray in which a substrate containing hole containing a substrate is formed so as to pass through in the thickness direction, a substrate supporting section provided with an annular section protruding from the side of a lower surface of the tray in a hole wall of the substrate containing hole, and a plurality of substrate contact sections formed in at least one of the hole wall and an upper surface of the annular section, the substrate contact sections supporting in contact with three or more plural points of an outer circumferential edge section on the side of a lower surface of the substrate contained in the substrate containing hole, the three or more plural points being spaced from each other in the circumferential direction, a dielectric member provided in the chamber, the dielectric member being provided with a tray supporting surface supporting the lower surface of the tray containing the substrate to be carried into the chamber, and a substrate placing section protruding upward from the tray supporting surface, the substrate placing section being inserted into the substrate containing hole from the side of the lower surface of the tray, the substrate placing section having a substrate placing surface serving as an upper end surface thereof on which the lower surface of the substrate is placed, an electrostatic chuck electrode at least partly built in the substrate placing section, the electrostatic chuck electrode for electrostatically attracting the substrate onto the substrate placing surface, a DC voltage application mechanism for applying DC voltage to the electrostatic chuck electrode, and a heat transfer gas supply mechanism for supplying a heat transfer gas to a space between the substrate and the substrate placing surface.

The three or more plural points of the outer circumferential edge section on the side of the lower surface of the substrate, the three or more plural points being spaced from each other in the circumferential direction, are in contact with the substrate contact sections of the substrate supporting section. In other words, the substrate contained in the substrate containing hole of the tray is not supported in a surface contact mode relative to the substrate supporting section but supported at the plural points on the substrate supporting section in a point contact mode. By supporting in a point contact mode, a contact area between the substrate contained in the substrate containing hole and the substrate supporting section of the tray is small. Thus, heat transfer from the tray to the substrate is suppressed. Therefore, even when the tray is carried out from the chamber after the plasma processing and moved from a vacuum environment to an atmospheric environment, a temperature increase of the substrate (particularly the outer circumferential edge section) due to the heat transfer from the tray can be reduced.

Specifically, the substrate contact sections of the substrate supporting section are protruding sections formed on the upper surface of the annular section.

Alternatively, the substrate contact sections of the substrate supporting section are protruding sections formed on the hole wall.

Further alternatively, the substrate contact sections of the substrate supporting section are protruding sections extending over the upper surface of the annular section and the hole wall.

Preferably, a heat transfer material layer is formed on at least one of the lower surface of the tray and the tray supporting surface.

With this configuration, a temperature increase of the tray itself during the plasma processing can be reduced. Thus, when the tray is carried out from the chamber after the plasma processing and moved from the vacuum environment to the atmospheric environment, the temperature increase of the substrate (particularly the outer circumferential edge section) due to the heat transfer from the tray can be more effectively reduced.

A second aspect of the present invention is to provide a plasma processing apparatus, including a chamber capable of being decompressed, a plasma generation source for generating plasma in the chamber, a tray in which a substrate containing hole containing a substrate is formed so as to pass through in the thickness direction, and in which a hole wall of the substrate containing hole is inclined by a first inclination angle relative to the horizontal direction toward center of the substrate containing hole, a substrate supporting section provided with an annular section protruding from the side of a lower surface of the tray in the hole wall, the annular section having a substrate contact section serving as an upper surface inclined by a second inclination angle which is smaller than the first inclination angle relative to the horizontal direction toward the center of the substrate containing hole, the substrate contact section supporting an outer circumferential edge section of the substrate contained in the substrate containing hole, a dielectric member provided in the chamber, the dielectric member being provided with a tray supporting surface supporting the lower surface of the tray containing the substrate to be carried into the chamber, and a substrate placing section protruding upward from the tray supporting surface, the substrate placing section being inserted into the substrate containing hole from the side of the lower surface of the tray, the substrate placing section having a substrate placing surface serving as an upper end surface thereof on which the lower surface of the substrate is placed, an electrostatic chuck electrode at least partly built in the substrate placing section, the electrostatic chuck electrode for electrostatically attracting the substrate onto the substrate placing surface, a DC voltage application mechanism for applying DC voltage to the electrostatic chuck electrode, and a heat transfer gas supply mechanism for supplying a heat transfer gas to a space between the substrate and the substrate placing surface.

The substrate contact section inclined by the inclination angle (second inclination angle) relative to the horizontal direction is in contact with the outer circumferential edge section on the side of the lower surface of the substrate. Thereby, the substrate contained in the substrate containing hole is supported on the substrate supporting section. Therefore, the substrate contained in the substrate containing hole of the tray is not supported in a surface contact mode relative to the substrate supporting section but supported at the plural points on the substrate supporting section in a point contact mode in a case of a substrate having a non-axisymmetric warp, and supported on the substrate supporting section in a line contact mode in a case of a substrate having an axisymmetric warp or a flat substrate having no warp. By supporting in a point contact mode or in a line contact mode, the contact area between the substrate contained in the substrate containing hole and the substrate supporting section of the tray is small. Thus, the heat transfer from the tray to the substrate is suppressed. Therefore, even when the tray is carried out from the chamber after the plasma processing and moved from the vacuum environment to an atmospheric environment, the temperature increase of the substrate (particularly the outer circumferential edge section) due to the heat transfer from the tray can be reduced.

Preferably, a heat transfer material layer is formed on at least one of the lower surface of the tray and the tray supporting surface.

With this configuration, the temperature increase of the tray itself during the plasma processing can be reduced. Thus, when the tray is carried out from the chamber after the plasma processing and moved from the vacuum environment to the atmospheric environment, the temperature increase of the substrate (particularly the outer circumferential edge section) due to the heat transfer from the tray can be more effectively reduced.

A third aspect of the present invention is to provide a plasma processing apparatus, including a chamber capable of being decompressed, a plasma generation source for generating plasma in the chamber, a tray in which a substrate containing hole containing a substrate is formed so as to pass through in the thickness direction, a substrate supporting section formed in a hole wall of the substrate containing hole, the substrate supporting section supporting an outer circumferential edge section of the substrate contained in the substrate containing hole, a dielectric member provided in the chamber, the dielectric member being provided with a tray supporting surface supporting a lower surface of the tray containing the substrate to be carried into the chamber, and a substrate placing section protruding upward from the tray supporting surface, the substrate placing section being inserted into the substrate containing hoe from the side of the lower surface of the tray, the substrate placing section having a substrate placing surface serving as an upper end surface thereof on which the lower surface of the substrate is placed, a heat transfer material layer formed at least one of the lower surface of the tray and the tray supporting surface, an electrostatic chuck electrode at least partly built in the substrate placing section, the electrostatic chuck electrode for electrostatically attracting the substrate onto the substrate placing surface, a DC voltage application mechanism for applying DC voltage to the electrostatic chuck electrode, and a heat transfer gas supply mechanism for supplying a heat transfer gas to a space between the substrate and the substrate placing surface.

Since the heat transfer material layer is formed on at least one of the lower surface of the tray and the tray supporting surface, heat transfer efficiency is high between the tray supporting surface of the dielectric member and the lower surface of the tray. As a result, the tray is effectively cooled due to direct heat transfer with the dielectric member during the plasma processing, so that the temperature increase of the tray during the plasma processing is reduced. The temperature increase of the tray itself is reduced. Thus, when the tray is carried out from the chamber after the plasma processing and moved from the vacuum environment to the atmospheric environment, the temperature increase of the substrate (particularly the outer circumferential edge section) due to the heat transfer from the tray can be reduced.

A fourth aspect of the present invention is to provide a plasma processing method for putting a tape base material having an insulating property between a tray supporting surface of a dielectric member of a substrate susceptor and a lower surface of a tray containing a substrate in a substrate containing hole, and placing the tray on the tray supporting surface, generating plasma and applying bias voltage to the substrate susceptor so as to generate a negative sheath potential on the tray placed on the tray supporting surface and polarize a potential in the tape base material, and making the tray electrostatically attract itself onto the tray supporting surface of the dielectric member with the polarized tape base material.

The lower surface of the tray is pushed onto the tray supporting surface by electrostatically attracting itself with the polarized tape base material. Thus, an adhesion property of the lower surface of the tray to the tray supporting surface during the plasma processing is increased. Therefore, during the plasma processing, the tray is effectively cooled due to the heat transfer with the dielectric member. As a result, the temperature increase of the tray itself is suppressed. Thus, when the tray is carried out from the chamber after the plasma processing and moved from the vacuum environment to the atmospheric environment, the temperature increase of the substrate (particularly the outer circumferential edge section) due to the heat transfer from the tray can be reduced.

In the plasma processing apparatus of the first and second aspects of the present invention, the substrate supporting section supporting the substrate contained in the substrate containing hole of the tray is provided with the substrate contact section in contact with the substrate in a point contact mode or in a line contact mode. Therefore, heat transfer efficiency from the tray to the substrate is low. Thus, when the tray is carried out from the chamber after the plasma processing and moved from the vacuum environment to the atmospheric environment, the temperature increase of the substrate (particularly the outer circumferential edge section) duo to the heat transfer from the tray can be reduced.

In the plasma processing apparatus of the third aspect of the present invention, the heat transfer material layer is formed on at least one of the lower surface of the tray and the tray supporting surface. Thus, the tray during the plasma processing is effectively cooled by the heat transfer with the dielectric member, so that the temperature increase is suppressed. Due to reduction of the temperature increase of this tray itself, when the tray is carried out from the chamber after the plasma processing and moved from the vacuum environment to the atmospheric environment, the temperature increase of the substrate due to the heat transfer from the tray can be reduced.

In the plasma processing method of the fourth aspect of the present invention, the lower surface of the tray is pushed onto the tray supporting surface by electrostatically attracting itself with the polarized tape base material. Thus, the adhesion property of the lower surface of the tray to the tray supporting surface during the plasma processing is increased. Therefore, during the plasma processing, the tray is effectively cooled due to the heat transfer with the dielectric member. As a result, the temperature increase of the tray itself is suppressed. Thus, when the tray is carried out from the chamber after the plasma processing and moved from the vacuum environment to the atmospheric environment, the temperature increase of the substrate (particularly the outer circumferential edge section) due to the heat transfer from the tray can be reduced.

With the plasma processing apparatus and the plasma processing method of the first to fourth aspects of the present invention, the temperature increase of the substrate due to the heat transfer from the tray after the plasma processing can be reduced. Thus, there is no need for providing a stand-by time for cooling by heat release, heat transfer, or the like, so that throughput can be improved. With the configuration that the substrate contact section of the substrate supporting section of the tray is in contact with the substrate in a point contact or line contact mode or the configuration that the heat transfer material layer is provided on the lower surface of the tray, that is, with the relatively simple configuration, the temperature increase of the substrate due to the heat transfer from the tray after the plasma processing can be reduced. Thus, simplification of the apparatus and cost reduction can be realized.

### BRIEF DESCRIPTION OF THE DRAWINGS

FIG. 1 is a schematic sectional view of a dry etching apparatus according to a first embodiment of the present invention;

FIG. 2 is a schematic plan view of the dry etching apparatus according to the first embodiment of the present invention;

FIG. 3A is a schematic sectional view of a substrate having a warp;

FIG. 3B is a schematic sectional view of a flat substrate having no warp;

FIG. 4A is a plan view of a tray capable of containing four discoid substrates;

FIG. 4B is a plan view of a tray capable of containing seven discoid substrates;

FIG. 4C is a plan view of a tray capable of containing nine rectangular-plate-shape substrates;

FIG. 5 is a perspective view showing a tray and a dielectric plate;

FIG. 6A is a plan view of the tray;

FIG. 6B is a sectional view by the line VI-VI of FIG. 6A;

FIG. 7A is an enlarged view of a part VII of FIG. 6A;

FIG. 7B is a sectional view by the line VII′-VII′ of FIG. 7A;

FIG. 7C is a partially perspective view of a part VII″ of FIG. 7A;

FIG. 8A is a partially enlarged view showing the vicinity of a hole wall of a substrate containing hole (the substrate is contained in the tray);

FIG. 8B is a partially enlarged view showing the vicinity of the hole wall of the substrate containing hole (the tray is lowered toward the dielectric plate);

FIG. 8C is a partially enlarged view showing the vicinity of the hole wall of the substrate containing hole (the tray is placed on a tray supporting surface of the dielectric plate);

FIG. 9A is a plan view of the dielectric plate;

FIG. 9B is a sectional view by the line IX-IX of FIG. 9A;

FIG. 10A is a partially enlarged view of FIG. 1 (the tray is positioned on the upper side of the dielectric plate);

FIG. 10B is a partially enlarged view of FIG. 1 (the tray is lowered toward the dielectric plate);

FIG. 10C is a partially enlarged view of FIG. 1 (the tray is placed on the tray supporting surface of the dielectric plate);

FIG. 11 is a schematic sectional view of the dry etching apparatus according to a second embodiment of the present invention;

FIG. 12 is a perspective view showing the tray and the dielectric plate;

FIG. 13A is a sectional view by the line XII-XII of FIG. 12;

FIG. 13B is a partially enlarged perspective view of the tray;

FIG. 14A is a partially enlarged view showing the vicinity of the hole wall of the substrate containing hole (the substrate is contained in the tray);

FIG. 14B is a partially enlarged view showing the vicinity of the hole wall of the substrate containing hole (the tray is lowered toward the dielectric plate);

FIG. 14C is a partially enlarged view showing the vicinity of the hole wall of the substrate containing hole (the tray is placed on the tray supporting surface of the dielectric plate).

FIG. 15A is a partially enlarged view of FIG. 11 (the tray is positioned on the upper side of the dielectric plate);

FIG. 15B is a partially enlarged view of FIG. 11 (the tray is lowered toward the dielectric plate);

FIG. 15C is a partially enlarged view of FIG. 11 (the tray is placed on the tray supporting surface of the dielectric plate);

FIG. 16 is a schematic sectional view of the dry etching apparatus according to the third embodiment of the present invention;

FIG. 17 is a perspective view showing the tray and the dielectric plate;

FIG. 18A is a sectional view by the line XVIII-XVIII of FIG. 17;

FIG. 18B is a partially enlarged perspective view of the tray;

FIG. 19A is a partially enlarged view showing the vicinity of the hole wall of the substrate containing hole (the substrate is contained in the tray);

FIG. 19B is a partially enlarged view showing the vicinity of the hole wall of the substrate containing hole (the tray is lowered toward the dielectric plate);

FIG. 19C is a partially enlarged view showing the vicinity of the hole wall of the substrate containing hole (the tray is placed on the tray supporting surface of the dielectric plate);

FIG. 20A is a partially enlarged view of FIG. 16 (the tray is positioned on the upper side of the dielectric plate);

FIG. 20B is a partially enlarged view of FIG. 16 (the tray is lowered toward the dielectric plate);

FIG. 20C is a partially enlarged view of FIG. 16 (the tray is placed on the tray supporting surface of the dielectric plate);

FIG. 21 is a sectional view of an alternative relating to a polyimide tape;

FIG. 22 is a sectional view of another alternative relating to the polyimide tape;

FIG. 23A is a partially plan view of the tray having a substrate supporting section of a first alternative;

FIG. 23B is a sectional view by the line XXIII-XXIII of FIG. 23A;

FIG. 23C is a partially enlarged perspective view of a part XXIII′ of FIG. 23A;

FIG. 24A is a partially plan view of the tray having the substrate supporting section of a second alternative;

FIG. 24B is a sectional view by the line XXIV-XXIV of FIG. 24A;

FIG. 24C is a partially enlarged perspective view of a part XXIV′ of FIG. 24A;

FIG. 25A is a partially plan view of the tray having the substrate supporting section of a third alternative;

FIG. 25B is a sectional view by the line XXV-XXV of FIG. 25A;

FIG. 25C is a partially enlarged perspective view of a part XXV′ of FIG. 25A;

FIG. 26A is a partially plan view of the tray having the substrate supporting section of a fourth alternative;

FIG. 26B is a sectional view by the line XXVI-XXVI of FIG. 26A;

FIG. 26C is a partially enlarged perspective view of a part XXVI′ of FIG. 26A;

FIG. 27A is a plan view showing an alternative of the dielectric plate; and

FIG. 27B is an enlarged sectional view by the line XXVII-XXVII of FIG. 27A;

### DETAILED DESCRIPTION OF THE INVENTION

### First Embodiment

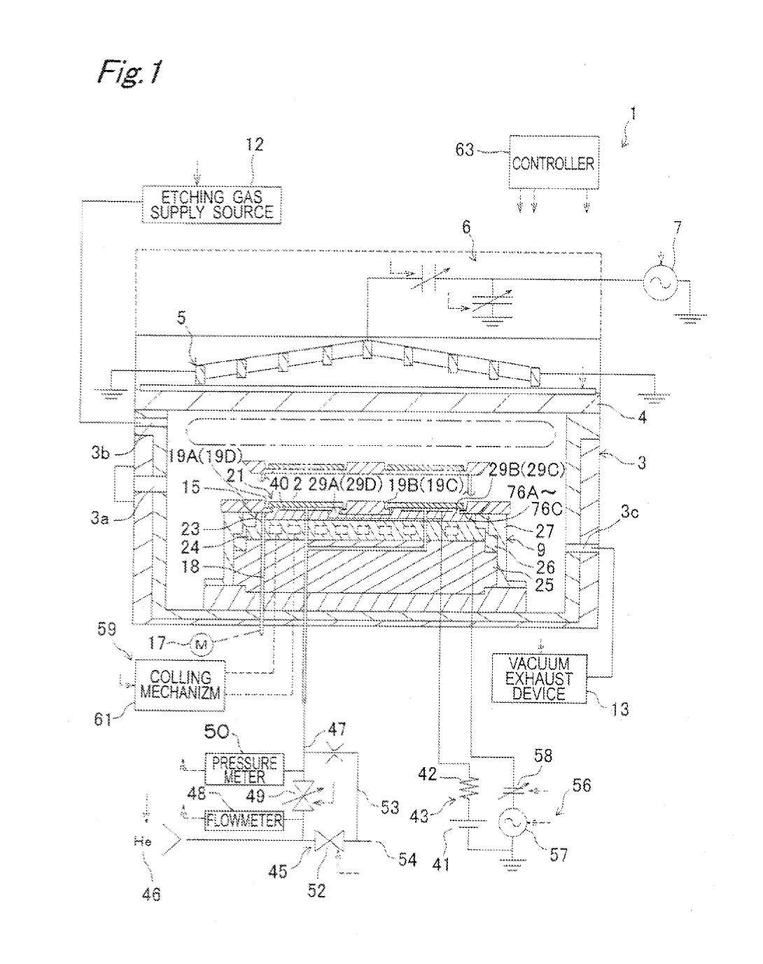

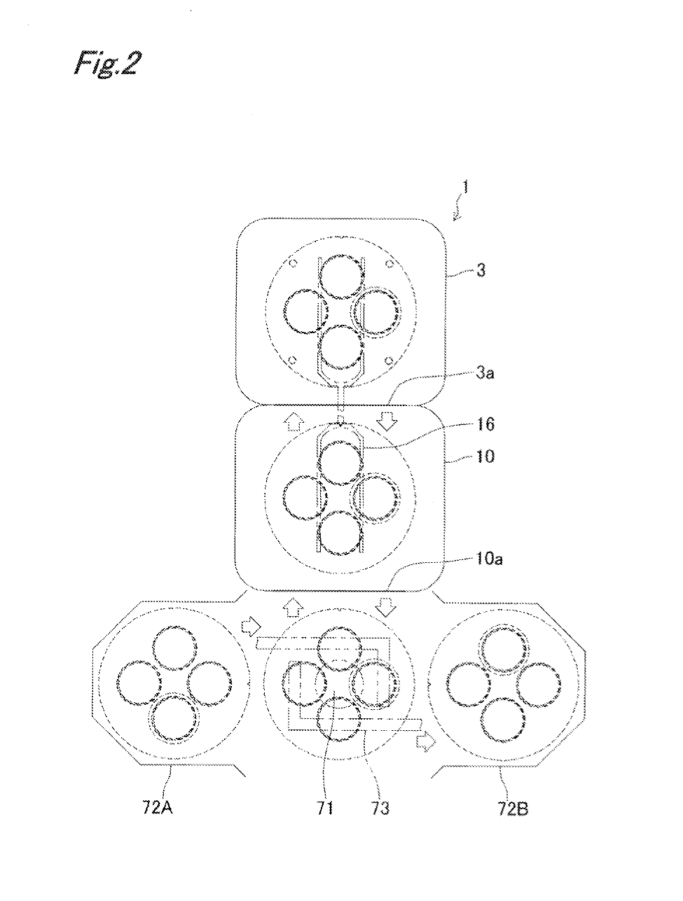

FIGS. 1 and 2 show an ICP (inductively-coupled plasma) type dry etching apparatus 1 according to a first embodiment of the present invention.

The dry etching apparatus 1 is provided with a chamber (vacuum chamber) 3 forming an etching chamber (processing chamber) inside which dry etching (plasma processing) is performed to substrates 2, the chamber 3 capable of being decompressed. An upper end opening of the chamber 3 is closed by a top plate 4 formed by a quartz dielectric body or the like in a sealed state. An ICP coil 5 is arranged on the top plate 4. A high frequency power source 7 is electrically connected to the ICP coil 5 via a matching circuit 6. A substrate susceptor 9 having a function as a lower part electrode to which bias voltage is applied and a function as a holding base for the substrates 2 is arranged on the side of a bottom part in the chamber 3 facing the top plate 4. The chamber 3 is provided with an openable and closable carrying gate 3a communicating with an adjacently provided load lock chamber 10 also serving as a carrying chamber (refer to FIG. 2). As described in detail later, a tray 15 containing plural (four in the present embodiment) substrates 2 is carried in and out between the chamber 3 and the load lock chamber 10 through the gate 3a. An etching gas supply source 12 is connected to an etching gas supply port 3b provided in the chamber 3. The etching gas supply source 12 is provided with a MFC (mass flow controller) and the like so as to be capable of supplying an etching gas from the etching gas supply port 3b at a desired flow rate. Further, a vacuum exhaust device 13 provided with a vacuum pump and the like is connected to an exhaust port 3c provided in the chamber 3. Furthermore, rising and lowering pins 18 passing through the substrate susceptor 9 and rising and lowering by drive of a drive device 17 are provided in the chamber 3.

With reference to FIG. 2, a known double-arm type carrying arm (vacuum carrying arm) 16 capable of moving straight in the horizontal direction and rotating on a horizontal plane is contained in the load lock chamber 10 in order to carry the tray 15 into and from the load lock chamber 10 itself and carry the tray 15 into and from the chamber 3. The load lock chamber 10 is provided with a mechanism for vacuuming and opening to atmosphere (not shown). An alignment base 71 is arranged on the outer side of a gate 10a of the load lock chamber 10 on the opposite side of the chamber 3. Cassettes 72A, 72B for respectively storing the tray 15 containing the substrates 2 before and after dry etching are arranged on the both sides of the alignment base 71. A carrying arm (atmosphere carrying arm) 73 is provided for bringing the tray 15 between the alignment base 71 and the cassettes 72A, 72B.

When the tray 15 is carried from the load lock chamber 10 into the chamber 3, as shown by a double chain line in FIG. 1, the rising and lowering pins 18 are at a rising position, and the tray 15 containing the substrates 2 is moved from the carrying arm 16 coming from the gate 3a into the chamber 3 to upper ends of the rising and lowering pins 18. In this state, the tray 15 is positioned on the upper side of the substrate susceptor 9 while being spaced from the substrate susceptor. Successively, the rising and lowering pins 18 lower to a lowering position shown by a solid line in FIG. 1, and thereby the tray 15 and the substrates 2 are placed on the substrate susceptor 9. At this time of placing, the substrates 2 are directly placed on the substrate susceptor 9 without putting the tray 15 inbetween (the substrates 2 are in a non-contact state with the tray 15). Meanwhile, at the time of carrying the tray 15 from the chamber 3 to the load lock chamber 10 after completion of plasma processing, the rising and lowering pins 18 rise to the rising position, and successively, the tray 15 is moved to the carrying arm 16 coming from the load lock chamber 10 into the chamber 3 via the gate 3a.

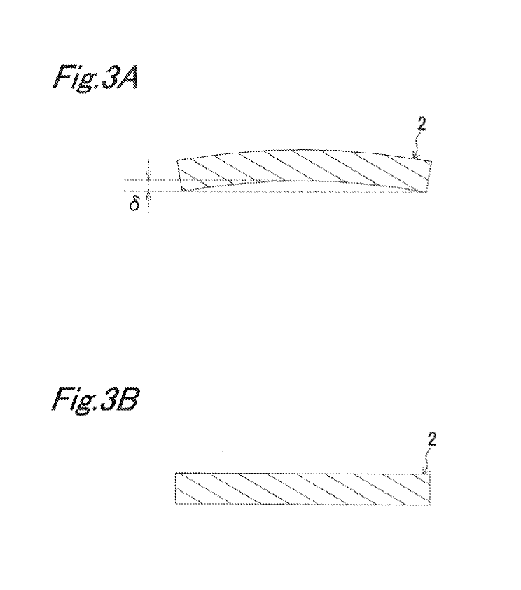

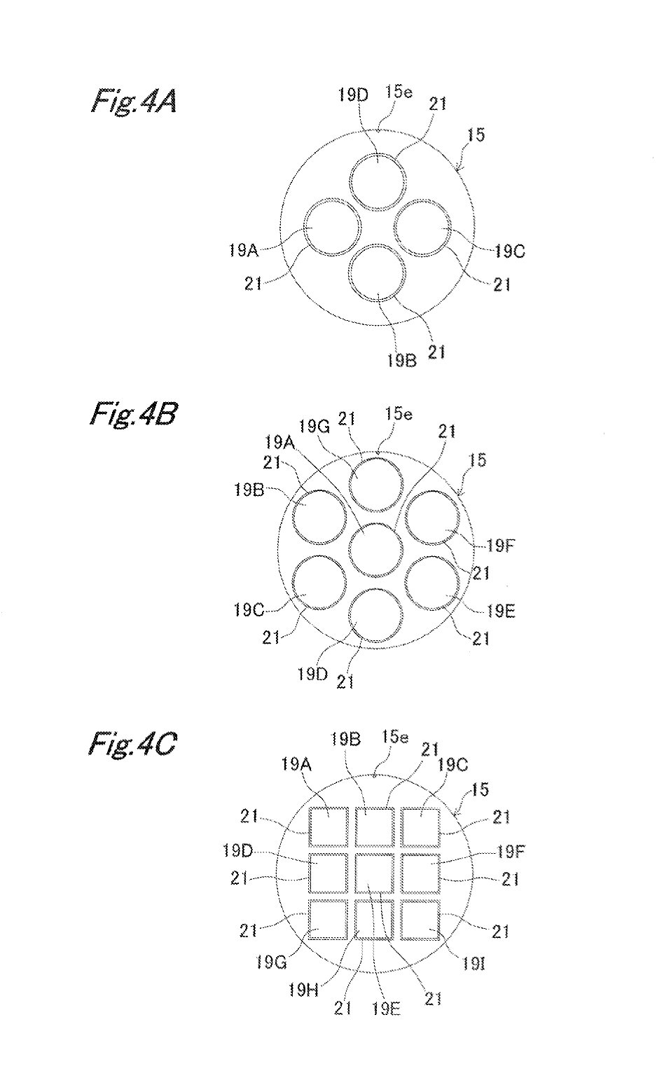

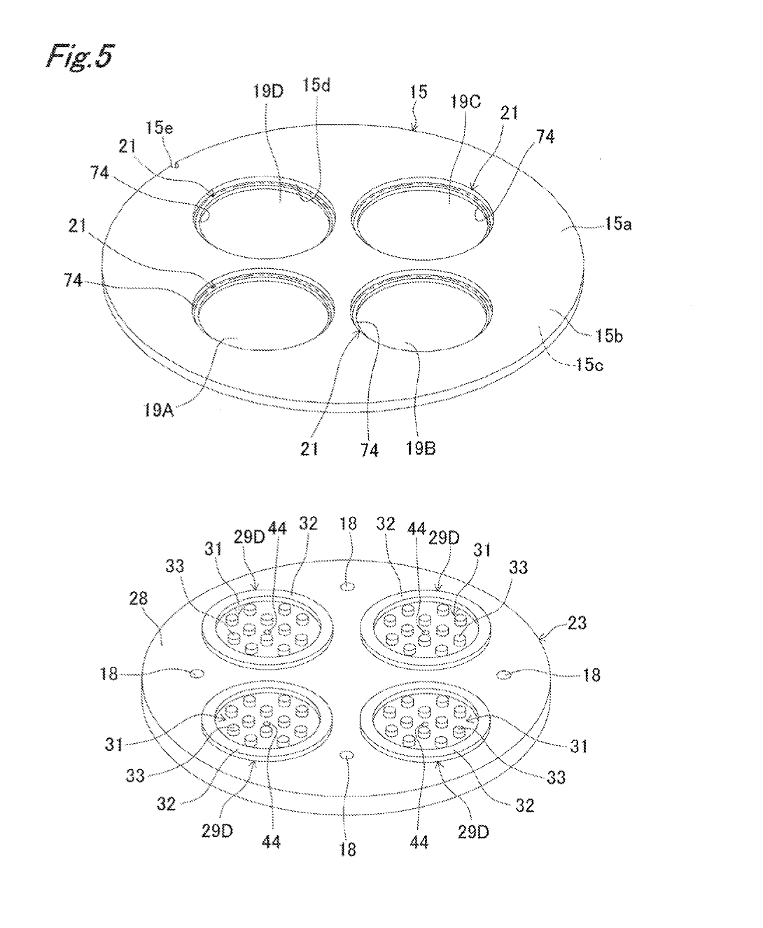

Hereinafter, the substrates 2 and the tray 15 will be briefly described with reference to FIGS. 3A to 4C.

The substrates 2 may be convexly warped substrates as shown in FIG. 3A or may be flat substrates having no warp as shown in FIG. 3B. The substrates 2 having a convex warp shown in FIG. 3A include, for example, substrates for manufacturing LEDs formed by epitaxially growing a GaN on a substrate made of a material such as GaN, SiC, and sapphire and forming a photoresist as a mask. When a GaN having thickness of about 5 to 10 μm is formed on a thin sapphire substrate of about 300 μm to 600 μm at a temperature of 600° C. to 1,000° C. with using MOCVD or the like, a warp convexed on the side of the film is generated due to a linear expansion coefficient difference between the sapphire substrate and the material of the film. A warp amount δ in a case of the substrates is about 100 μm in a case of the substrates of 3 inches (about 76.2 mm). With the dry etching apparatus 1 of the present embodiment, GaN processing for forming a contact for example can be performed to such GaN/sapphire substrates. The warp of the substrates 2 may be non-axisymmetric or axisymmetric. The flat substrates 2 having no warp shown in FIG. 3B include, for example, sapphire substrates for manufacturing the LEDs formed by forming the photoresist as the mask. With the dry etching apparatus 1 of the present embodiment, processing of making concave and convex parts for obtaining high brightness of the LED can be performed to such sapphire substrates. However, a material of the substrates 2 subjected to the processing by the dry etching apparatus 1 of the present embodiment is not limited to these.

With reference to FIGS. 4A to 4C, substrate containing holes 19A to 191 passing through in the thickness direction for containing the substrates 2 are formed in the tray 15. Substrate supporting sections 21 for holding the contained substrates 2 are respectively provided in the substrate containing holes 19A to 191. The tray 15 of FIG. 4A is provided with four substrate containing holes 19A to 19D for containing the discoid substrates 2. Meanwhile, the tray 15 of FIG. 4B is provided with seven substrate containing holes 19A to 19G for containing the discoid substrates 2. For example, in a case where a diameter of the tray 15 is 200 mm, as shown in FIG. 4A, the four substrate containing holes 19A to 19D for containing the substrates 2 having diameters of 3 inches can be provided in the tray 15. In this case, as shown in FIG. 4B, the seven substrate containing holes 19A to 19G for containing the substrates 2 having diameters of 2 inches (50.8 mm) can be provided in the tray 15. The substrates 2 to be contained in the tray 15 are not limited to discoid substrates but may be formed into other shapes including a rectangular-plate shape. For example, nine substrate containing holes 19A to 19I for containing the rectangular substrates 2 are provided in the tray 15 of FIG. 4C. In the present embodiment, the substrates 2 are discoid, and the tray 15 is provided with the four substrate containing holes 19A to 19D for containing the discoid substrates 2 as shown in FIG. 4A.

Hereinafter, the tray 15 in the present embodiment will be described in detail with reference to FIGS. 5 to 8C.

The tray 15 is provided with a thin-plate discoid tray main body 15a. A material of the tray 15 includes, for example, ceramic materials such as alumina (Al₂O₃), aluminum nitride (AlN), zirconia (ZrO), yttria (Y₂O₃), silicon nitride (SiN), and silicon carbide (SiC), and metal such as aluminum covered with anodized aluminum, aluminum with a surface thereof thermally sprayed with the ceramic material, and aluminum covered with a resin material. It is thought that in a case of a Cl-based process, alumina, yttria, silicon carbide, aluminum nitride, and the like are adopted, and in a case of an F-based process, quartz, a crystal, yttria, silicon carbide, aluminum thermally sprayed with anodized aluminum, and the like are adopted.

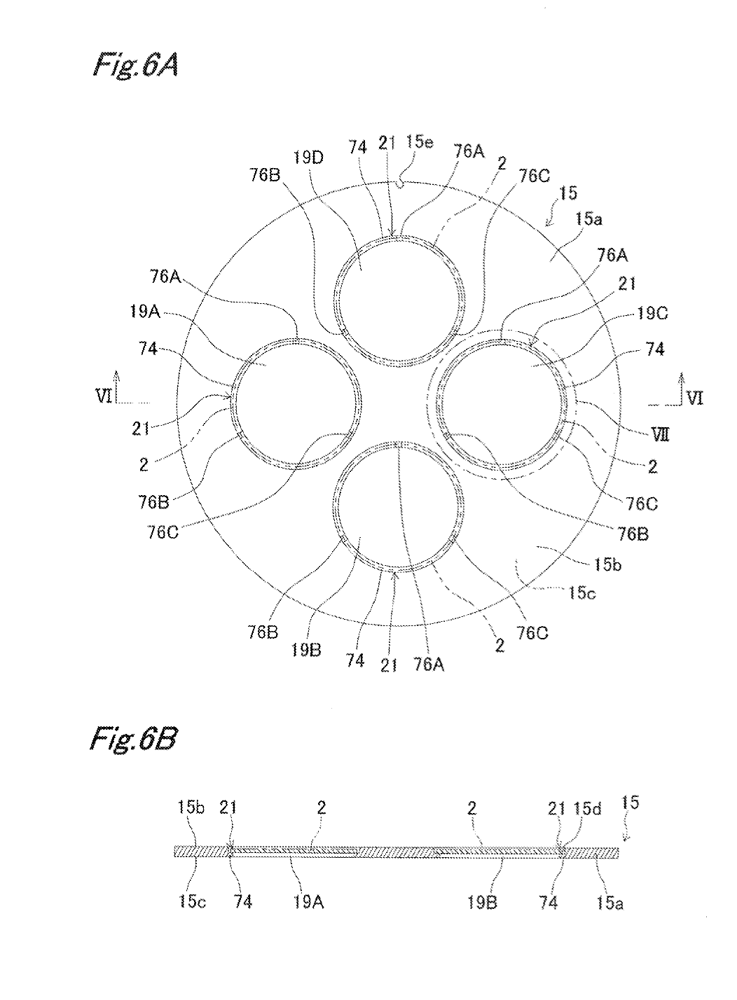

As shown in FIGS. 5 to 6B, the four substrate containing holes 19A to 19D formed into a circular shape in plan view, the substrate containing holes passing thorough from an upper surface 15b to a lower surface 15c in the thickness direction are provided in the tray main body 15a. These substrate containing holes 19A to 19D are arranged so as to be spaced from each other at regular angles relative to center of the tray main body 15a seen from the upper surface 15b and the lower surface 15c. A positioning cutout 15e to be engaged with a positioning protruding section (not shown) provided in the carrying arm 16 (refer to FIG. 2) is formed in the tray main body 15a.

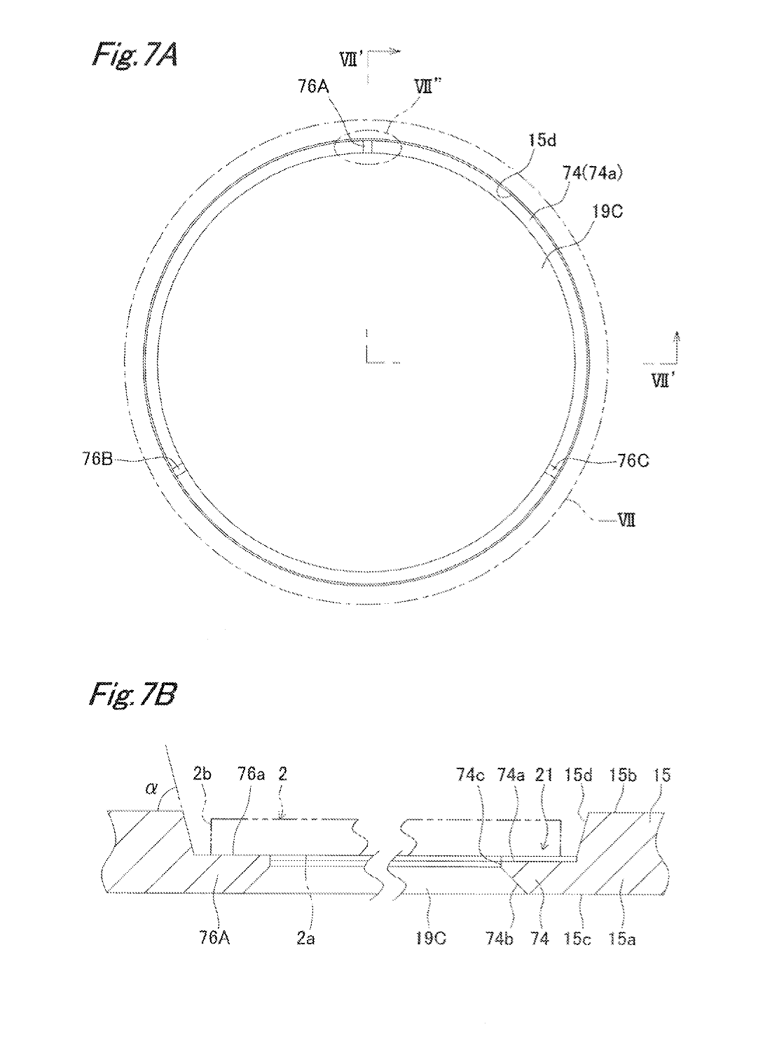

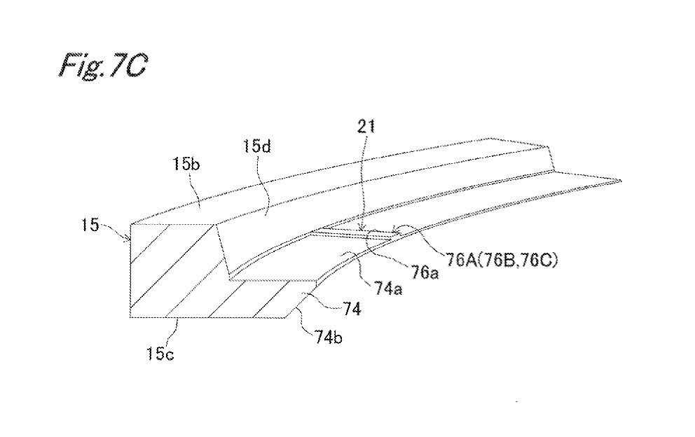

The substrate supporting sections 21 are respectively provided in the substrate containing holes 19A to 19D. As most clearly shown in FIGS. 7A to 7C, each of the substrate supporting sections 21 is provided with an annular section 74 protruding from the side of the lower surface 15c of the tray 15 in a hole wall 15d in each of the substrate containing holes 19A to 19D. The hole wall 15d in each of the substrate containing holes 19A to 19D is an inclined wall surface. Specifically, the hole wall 15d has an inclination angle a (such as 75°) relative to the horizontal direction toward center of each of the substrate containing holes 19A to 19D (refer to FIG. 7B). As most clearly shown in FIG. 7A, the annular section 74 is formed into a ring shape having narrow width provided in the entire circumference of the hole wall 15d. A protruding amount from the hole wall 15d of the annular section 74 is constant over the entire circumference. Further, an upper surface 74a of the annular section 74 is a flat surface extending in the horizontal direction, and a lower surface 74h is an inclined surface obliquely upward inclined toward a front end surface 74c (center of each of the substrate containing holes 19A to 19D).

The substrate supporting section 21 is provided with a plurality of (three in the present embodiment) protruding sections (substrate contact sections) 76A, 76B, 76C. The protruding sections 76A to 76C are provided on the upper surface 74a of the annular section 74. As shown in FIG. 7A, the protruding sections 76A to 76C are arranged so as to be spaced from each other at regular angles (at 120°) relative to the center of each of the substrate containing holes 19A to 19D in plan view. The protruding sections 76A to 76C extend the radial direction of each of the substrate containing holes 19A to 19D in plan view. Further, the protruding sections 76A to 76C extend over the entire width of the annular section 74. Specifically, the protruding sections 76A to 76C extend from a connection position between the upper surface 74a of the annular section 74 and the hole wall 15d of each of the substrate containing holes 19A to 19D to a connection position between the upper surface 74a of the annular section 74 and the front end surface 74c.

As most clearly shown in FIG. 7C, the protruding sections 76A to 76C protrude upward in the vertical direction from the upper surface 74a of the annular section 74. The protruding sections 76A to 76C are formed into a rectangular shape with a section orthogonal to the extending direction being elongated in the horizontal direction. A protruding amount of the protruding sections 76A to 76C from the upper surface 74a of the annular section 74 is constant over the extending direction, and upper surfaces 76a of the protruding sections 76A to 76C are flat surfaces extending in the horizontal direction. Regarding size of the protruding sections 76A to 76C, for example, width is about 1 mm to 2 mm, and the protruding amount from the upper surfaces 76a is 0.2 mm to 0.5 mm.

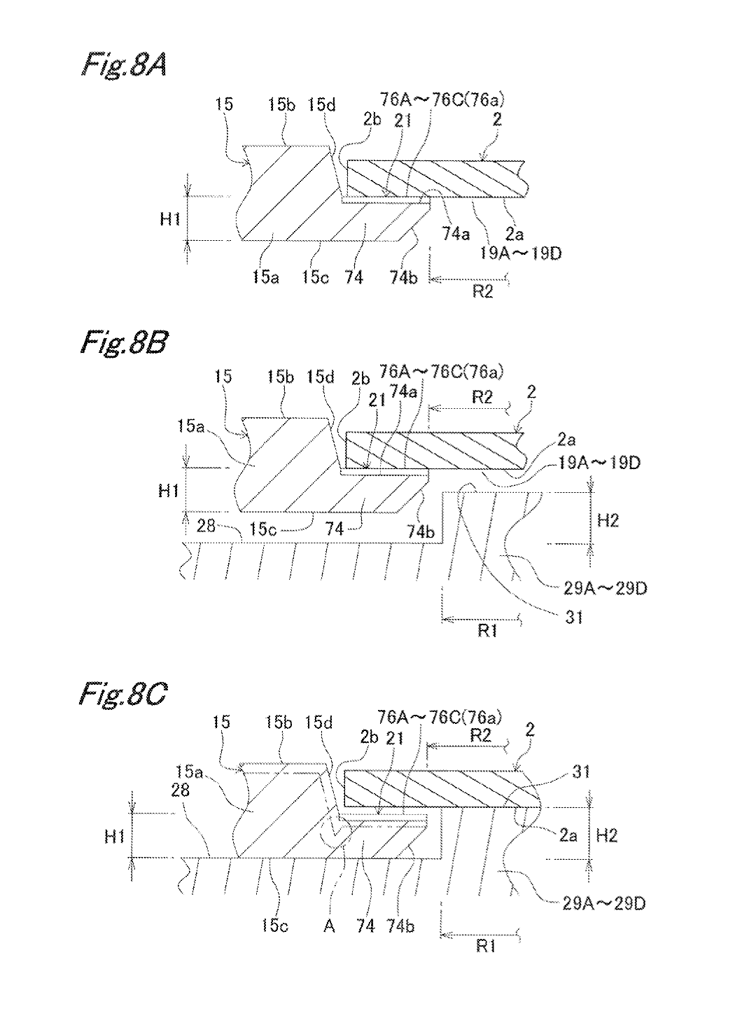

The substrate 2 contained in each of the substrate containing holes 19A to 19D is supported on the substrate supporting section 21. In detail, as shown in FIGS. 7B, 8A, and 8B, a lower surface 2a of an outer circumferential edge section of the substrate 2 contained in each of the substrate containing holes 19A to 19D is placed on the upper surfaces 76a of the protruding sections 76A to 76C, and thereby the substrate 2 is supported. The substrate 2 contained in each of the substrate containing holes 19A to 19D is in contact with the substrate supporting section 21 (tray 15) only on the upper surfaces 76a of the three protruding sections 76A to 760 arranged so as to be spaced from each other at angles. Parts of the lower surface 2a of the outer circumferential edge section of the substrate 2 contained in each of the substrate containing holes 19A to 19D, the parts not corresponding to the protruding sections 76A to 76C, are positioned on the upper side of the upper surface 74a of the annular section 74 while being spaced from the upper surface, and in no contact with the substrate supporting section 21 (tray 15). That is, the lower surface 2a of the outer circumferential edge section of the substrate 2 contained in each of the substrate containing holes 19A to 19D is in contact with the upper surfaces 76a of the protruding sections 76A to 76C at three points spaced from each other in the circumferential direction. Thus, irrespective of having the warp (refer to FIGS. 3A and 3B), the lower surface is supported on the substrate supporting section 21 in a point contact mode (three-point support). Four or more protruding sections similar to the protruding sections 76A to 76C may be provided.

When the substrate 2 is contained in each of the substrate containing holes 19A to 19D, the substrate 2 is brought into each of the substrate containing holes 19A to 19D from the side of the upper surface 15b of the tray 15. At this time, the outer circumferential edge section of the substrate 2 (more specifically, an edge of a connection part between the lower surface 2a and an end surface 2b) is guided by the hole wall 15d having the inclination angle α relative to the horizontal direction. By guiding with this hole wall 15d, a position of the substrate 2 in plan view is set (refer to FIG. 6A), and the substrate is contained in each of the substrate containing holes 19A to 19D in a horizontal posture. As a result, the three points on the lower surface 2a of the outer circumferential edge section of the substrate 2 are reliably placed on the upper surfaces 76a of the protruding sections 76A to 76C.

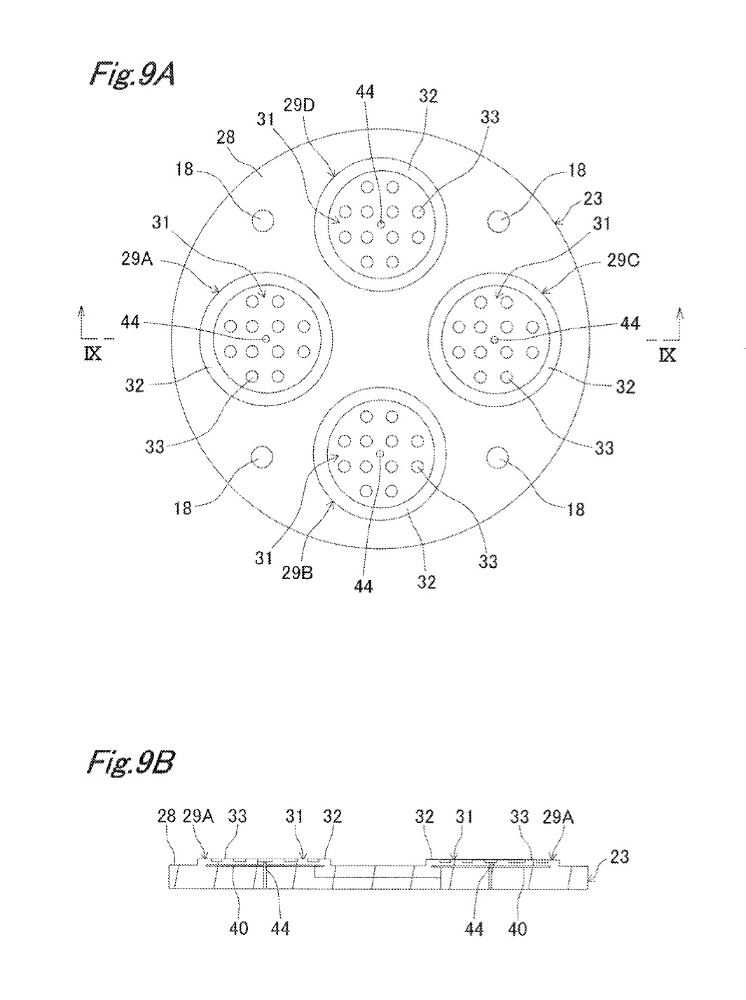

Next, the substrate susceptor 9 will be described with reference to FIGS. 1, 5, and 9A to 10C. Firstly, with reference to FIG. 1, the substrate susceptor 9 is provided with a dielectric plate (dielectric member) 23 made of a ceramic material or the like, a metal plate (supporting member) 24 made of aluminum with a surface coated with anodized aluminum, the metal plate functioning as a pedestal electrode in the present embodiment, a spacer plate 25 made of a ceramic material, a guide tubular body 26 made of a ceramic material, and a grounding shield 27 made of metal. The dielectric plate 23 forming an uppermost part of the substrate susceptor 9 is fixed to an upper surface of the metal plate 24. The metal plate 24 is fixed onto the spacer plate 25. Further, an outer periphery of the dielectric plate 23 and the metal plate 24 is covered with the guide tubular body 26, and the outer side thereof and an outer periphery of the spacer plate 25 are covered with the grounding shield 27.

With reference to FIGS. 5 and 9A to 10C, the entire dielectric plate 23 is formed into a thin discoid shape, and an outer shape in plan view is circular. An upper end surface of the dielectric plate 23 forms a tray supporting surface (tray supporting section) 28 supporting the lower surface 15c of the tray 15. Four short cylindrical substrate placing sections 29A to 29D respectively corresponding to the substrate containing holes 19A to 19D of the tray 15 protrude upward from the tray supporting surface 28. The dielectric body plate 23 may be a single body member or have a divided structure formed by a plurality of members divided in the thickness direction.

An upper end surface of each of the substrate placing sections 29A to 29D serves as a substrate placing surface 31 on which the lower surface 2a of the substrate 2 is placed. A ring shape projecting section 32 protruding upward from an outer peripheral edge of the substrate placing surface 31 and supporting the lower surface 2a of the substrate 2 with an upper end surface thereof is provided in each of the substrate placing sections 29A to 29D. A plurality of cylindrical protruding sections 33 having a sufficiently smaller diameter than the substrate placing surface 31 is provided in a part of the substrate placing surface 31 surrounded by the ring shape projecting section 32 so as to be uniformly distributed. Not only the ring shape projecting section 32 but also upper end surfaces of the cylindrical protruding sections 33 support the lower surface 2a of the substrate 2.

With reference to FIGS. 8A to 8C, an outer diameter R1 of the substrate placing sections 29A to 29D is set to be smaller than a diameter R2 of a circular opening 36 surrounded by the front end surface 74c of the annular section 74 of the substrate supporting section 21. Therefore, when the tray 15 is lowered toward the dielectric plate 23 at the time of carrying in as described above, the substrate placing sections 29A to 29D respectively come into the corresponding substrate containing holes 19A to 19D from the side of the lower surface 15c of the tray main body 15a, and the lower surface 15c of the tray 151s placed on the tray supporting surface 28 of the dielectric plate 23. Height H1 from the lower surface 15c of the tray main body 15a to an upper end (upper surfaces 76a of the protruding sections 76A to 76C) of the substrate supporting section 21 is set to be lower than height H2 from the tray supporting surface 28 to the substrate placing surface 31. Therefore, in a state that the lower surface 15c of the tray 15 is placed on the tray supporting surface 28, the substrate 2 is pushed up by the substrate placing surface 31 in an upper end of each of the substrate placing sections 29A to 29D, and floated up from the substrate supporting section 21 (protruding sections 76A to 76C) of the tray 15. In other words, when the tray 15 containing the substrate 2 in each of the substrate containing holes 19A to 19D is placed on the tray supporting surface 28 of the dielectric plate 23, the lower surface 2a of the substrate 2 contained in each of the substrate containing holes 19A to 19D is floated up and separated from the upper surfaces 76a of the protruding sections 76A to 76C of the substrate supporting section 21 to the upper side by a predetermined amount (in no contact with the protruding sections 76A to 76C), and supported on the substrate placing surface 31. The outer circumferential edge section of the substrate 2 supported on the substrate placing surface 31 are spaced from the tray 15, specifically the hole wall 15d and the upper surface 74a of the annular section 74 in the each of the substrate containing holes 19A to 19D.

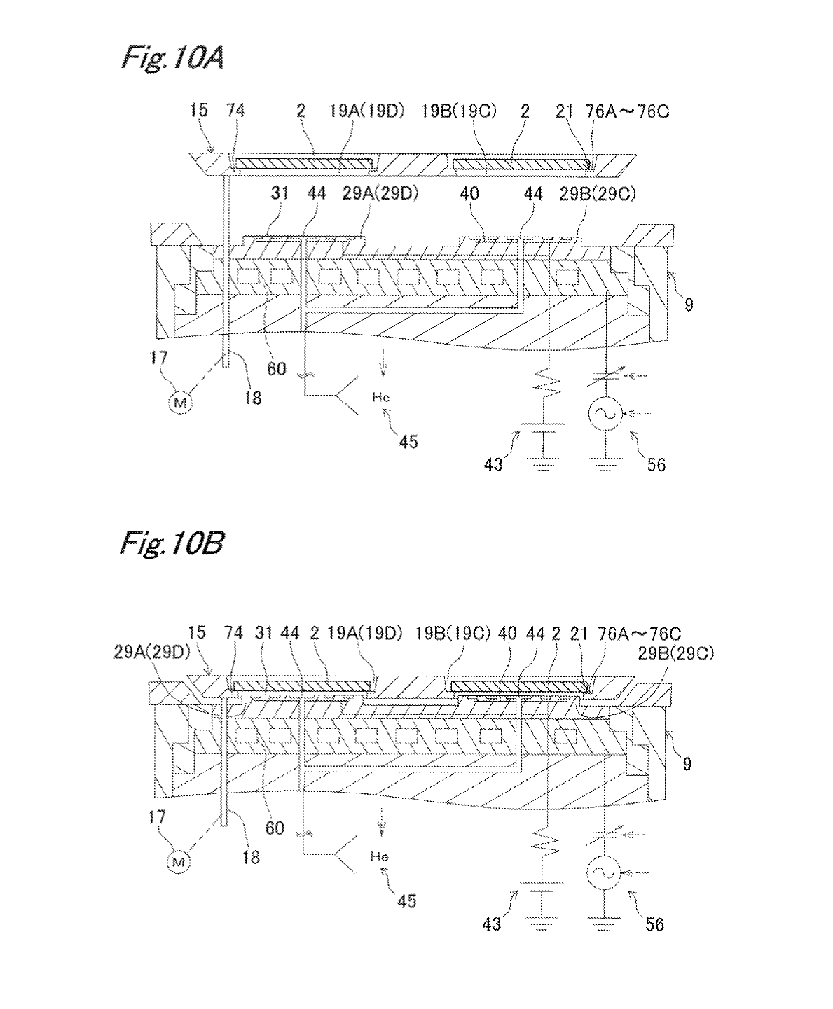

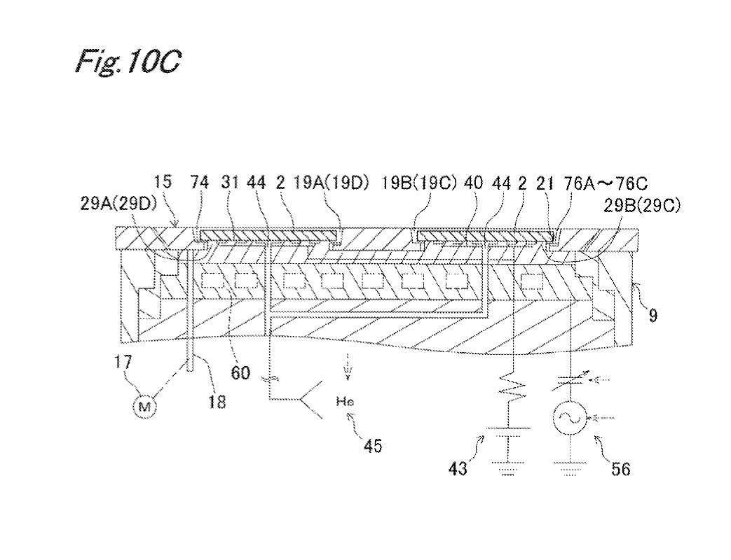

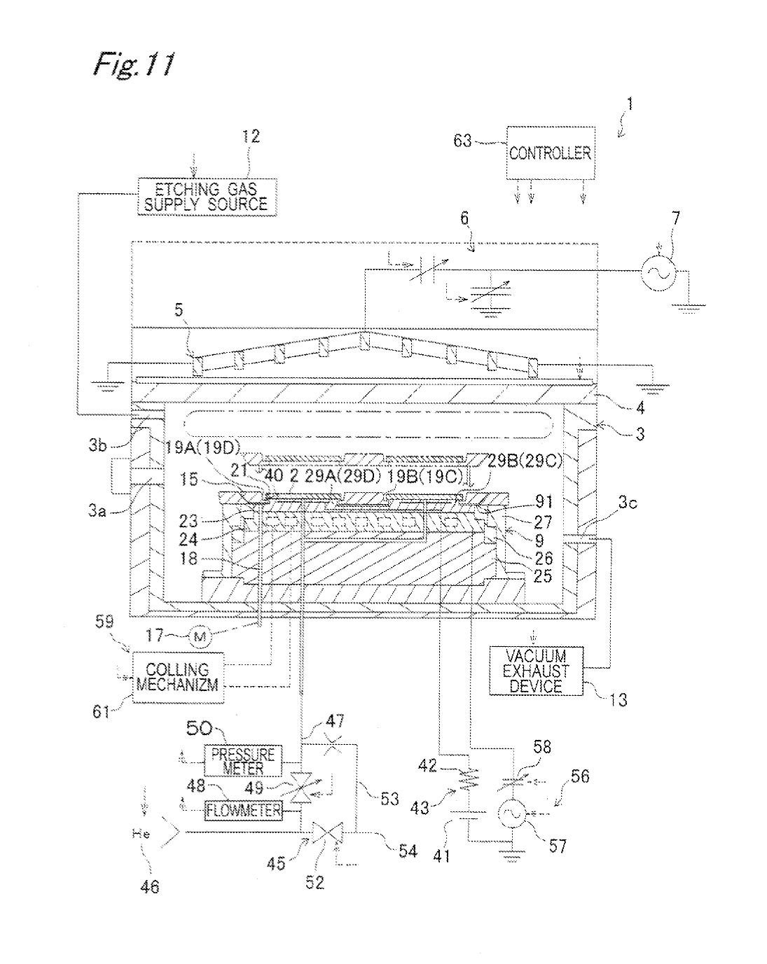

With reference to FIGS. 1 and 10A to 10C, monopolar electrostatic chuck electrodes 40 are respectively built in the vicinity of the substrate placing surfaces 31 in the substrate placing sections 29A to 29D of the dielectric plate 23. In the present embodiment, these electrostatic chuck electrodes 40 are formed into a flat plate shape. The electrostatic chuck electrodes 40 are electrically insulated from each other, and DC voltage for electrostatic chuck is applied from a common DC voltage application mechanism 43 provided with a DC power source 41, a resistance 42 for adjustment, and the like. The electrostatic chuck electrodes may be bipolar. One electrostatic chuck electrode may be provided commonly for the substrate placing sections 29A to 29D.

With reference to FIGS. 5, 9A, 9B, and 10A to 10C, supply holes 44 for a heat transfer gas (helium in the present embodiment) are respectively provided in the substrate placing surfaces 31 in the substrate placing sections 29A to 29D. These supply holes 44 are connected to a common heat transfer gas supply mechanism 45 (shown in FIG. 1). The heat transfer gas supply mechanism 45 is provided with a heat transfer gas source (helium gas source in the present embodiment) 46, a supply flow passage 47 running from the heat transfer gas source 46 to the supply hole 44, and a flowmeter 48, a flow rate control valve 49, and a pressure meter 50 provided in this order from the side of the heat transfer gas source 46 in the supply flow passage 47. The heat transfer gas supply mechanism 45 is provided with a discharge flow passage 51 diverging from the supply flow passage 47, and a cut-off valve 52 provided in this discharge flow passage 51. Further, the heat transfer gas supply mechanism 45 is provided with a bypass flow passage 53 connecting the supply flow passage 47 on the side of the supply hole 44 relative to the pressure meter 50 and the discharge flow passage 51. The heat transfer gas is supplied by the heat transfer gas supply mechanism 45 to a space between the substrate placing surface 31 in each of the substrate placing sections 29A to 29D and the lower surface 2a of the substrate 2 placed thereon, in detail, an enclosed space surrounded by the lower surface 2a of the substrate 2 and the ring shape projecting section 32. At the time of supplying the heat transfer gas, the cut-off valve 52 is closed, and the heat transfer gas is fed from the heat transfer gas source 46 to the supply hole 44 via the supply flow passage 47. Based on a flow rate and pressure of the supply flow passage 47 detected by the flowmeter 48 and the pressure meter 50, a controller 63 described later controls the flow rate control valve 49. Meanwhile, at the time of discharging the heat transfer gas, the cut-off valve 52 is opened, and the heat transfer gas between the lower surface 2a of the substrate 2 and the substrate placing surface 31 is exhausted from an exhaust port 54 via the supply hole 44, the supply flow passage 47, and the discharge flow passage 51.

A high frequency application mechanism 56 for applying bias voltage serving as high frequency voltage for generating plasma is electrically connected to the metal plate 24. The high frequency application mechanism 56 is provided with a high frequency power source 57 and a variable capacitor 58 for matching.

A cooling mechanism 59 for cooling the metal plate 24 is also provided. The cooling mechanism 59 is provided with a coolant flow passage 60 formed in the metal plate 24, and a coolant circulation device 61 for circulating a coolant having an adjusted temperature in the coolant flow passage 60.

Based on various sensors including the flowmeter 48 and the pressure meter 50 and operational inputs, the controller 63 shown in FIG. 1 controls operation of the entire dry etching apparatus 1 including the high frequency power source 7, the etching gas supply source 12, the carrying arms 16, 73, the vacuum exhaust device 13, the drive device 17, the DC voltage application mechanism 43, the heat transfer gas supply mechanism 45, the high frequency application mechanism 56, and the cooling mechanism 59.

Next, the operation of the dry etching apparatus 1 of the present embodiment will be described.

Firstly, the substrate 2 is contained in each of the substrate containing holes 19A to 19D of the tray 15. The substrate 2 supported on the substrate supporting section 21 of the tray 15 is exposed from the lower surface 15c of the tray main body 15a by each of the substrate containing holes 19A to 19D when seen from the side of the lower surface of the tray main body 15a. The lower surface 2a of the outer circumferential edge section of the substrate 2 contained in each of the substrate containing holes 19A to 19D is supported on the upper surfaces 76a of the three protruding sections 76A to 76C of the substrate supporting section 21 of the tray 15 in a point contact mode. The tray 15 containing the substrates 2 is put in the cassette 72A.

Next, the carrying arm 73 takes out the tray 15 containing the four substrates 2 from the cassette 72A and places the tray on the alignment base 71. The alignment base 71 executes alignment adjustment of the tray 15. Meanwhile, the load lock chamber 10 is opened to the atmosphere.

Successively, the carrying arm 73 carries the tray 15 from the alignment base 71 into the load lock chamber 10 via the gate 10a. After the tray 15 is carried in, the load lock chamber 10 is vacuumed.

Next, the carrying arm 16 carries the tray 15 from the load lock chamber 10 into the chamber 3 already decompressed by the vacuum exhaust device 13 via the gate 3a. As shown by the double chain line in FIG. 1, the tray 1 is arranged on the upper side of the substrate susceptor 9 so as to be spaced from the substrate susceptor.

As shown in FIG. 10A, the rising and lowering pins 18 driven by the drive device 17 rise, and the tray 15 is moved from the carrying arm 16 to the upper ends of the rising and lowering pins 18. After moving the tray 15, the carrying arm 16 is returned to the load lock chamber 10, and the gate 3a is closed.

The rising and lowering pins 18 supporting the tray 15 on the upper ends lower from the rising position shown by the double chain line in FIG. 1 toward the substrate susceptor 9. With reference to FIGS. 8B, 8C, 10B, and 10C, the lower surface 15c of the tray 15 is lowered to the tray supporting surface 28 of the dielectric plate 23 of the substrate susceptor 9, and the tray 15 is supported on the tray supporting surface 28 of the dielectric plate 23. When the tray 15 is lowered toward the tray supporting surface 28, the substrate placing sections 29A to 29D of the dielectric plate 23 respectively come into the corresponding substrate containing holes 19A to 19D of the tray 15 from the side of the lower surface 15c of the tray 15. With the lower surface 15c of the tray 15 being brought close to the tray supporting surface 28, the substrate placing surface 31 in a front end of each of the substrate placing sections 29A to 29D goes toward the upper surface 15b of the tray 15 in each of the substrate containing holes 19A to 19D. As shown in FIGS. 8C and 10C, when the lower surface 15c of the tray 15 is placed on the tray supporting surface 28 of the dielectric plate 23, the substrate 2 in each of the substrate containing holes 19A to 19D is brought up from the upper surfaces 76a of the protruding sections 76A to 76C of the substrate supporting section 21 by each of the substrate placing sections 29A to 29D. In detail, the lower surface 2a of the substrate 2 is placed on the substrate placing surface 31 in each of the substrate placing sections 29A to 29D, and the substrate is arranged on the upper side of the upper surfaces 76a of the protruding sections 76A to 76C in the substrate supporting section 21 of the tray 15 so as to be spaced from the upper surfaces.

In such a way, since the substrate placing sections 29A to 29D come into the substrate containing holes 19A to 19D of the tray 15, the substrate 2 is placed on the substrate placing surface 31. Therefore, all the four substrates 2 contained in the tray 15 are respectively placed on the substrate placing surfaces 31 of the substrate placing sections 29A to 29D with high positioning precision.

Successively, high frequency voltage is applied from the high frequency power source 7 to the ICP coil 5, so that the plasma is generated (ignition).

Next, the DC voltage is applied from the DC voltage application mechanism 43 to the electrostatic chuck electrode 40 built in the dielectric plate 23, and the substrate 2 is electrostatically attracted to the substrate placing surface 31 in each of the substrate placing sections 29A to 29D. The lower surface 2a of the substrate 2 is directly placed on the substrate placing surface 31 without putting the tray 15 inbetween. Therefore, the substrate 2 is held onto the substrate placing surface 31 with a high degree of close attachment.

Further, the heat transfer gas is supplied from the heat transfer gas supply mechanism 45 to the space surrounded by the ring shape projecting section 32 in each of the substrate placing sections 29A to 29D and the lower surface 2a of the substrate 2 through the supply hole 44, and the heat transfer gas is charged in this space.

After that, the etching gas is supplied from the etching gas supply source 12 into the chamber 3, and predetermined pressure is maintained inside the chamber 3 by the vacuum exhaust device 13. The high frequency voltage applied from the high frequency power source 7 to the ICP coil 5 is boosted, and the bias voltage is applied to the metal plate 24 of the substrate susceptor 9 by the high frequency application mechanism 56. Then, etching is performed to the substrate 2 with the plasma. Since the four substrates 2 can be placed on the substrate susceptor 9 with one tray 15, batch processing can be performed.

During the etching, the coolant is circulated in the coolant flow passage 60 by the coolant circulation device 61, so that the metal plate 24 is cooled. Thereby, the dielectric plate 23 and the substrate 2 held onto the substrate placing surface 31 of the dielectric plate 23 are cooled. As described above, the lower surface 2a of the substrate 2 is directly placed on the substrate placing surface 31 without putting the tray 15 inbetween, and the substrate is held with a high degree of close attachment. Therefore, a sealing degree of the space surrounded by the ring shape projecting section 32 and the lower surface 2a of the substrate 2, the space in which the heat transfer gas is charged, is high, and a heat transfer property between the substrate 2 and the substrate placing surface 31 via the heat transfer gas is favorable. As a result, the substrate 2 held onto the substrate placing surface 31 in each of the substrate placing sections 29A to 29D can be cooled at high cooling efficiency. Thus, higher frequency power is supplied, so that efficiency of the dry etching can be improved. A temperature of the substrate 2 can be controlled with high precision. The heat transfer gas is charged into the space surrounded by the ring shape projecting section 32 in each of the substrate placing sections 29A to 29D and the lower surface 2a of each substrate 2. In other words, the space into which the heat transfer gas is charged is different from one substrate 2 to another. In this point, the heat transfer property between the substrate 2 and the substrate placing surface 31 of the dielectric plate 23 is also favorable, and temperature control with high cooling efficiency and high precision can be realized.

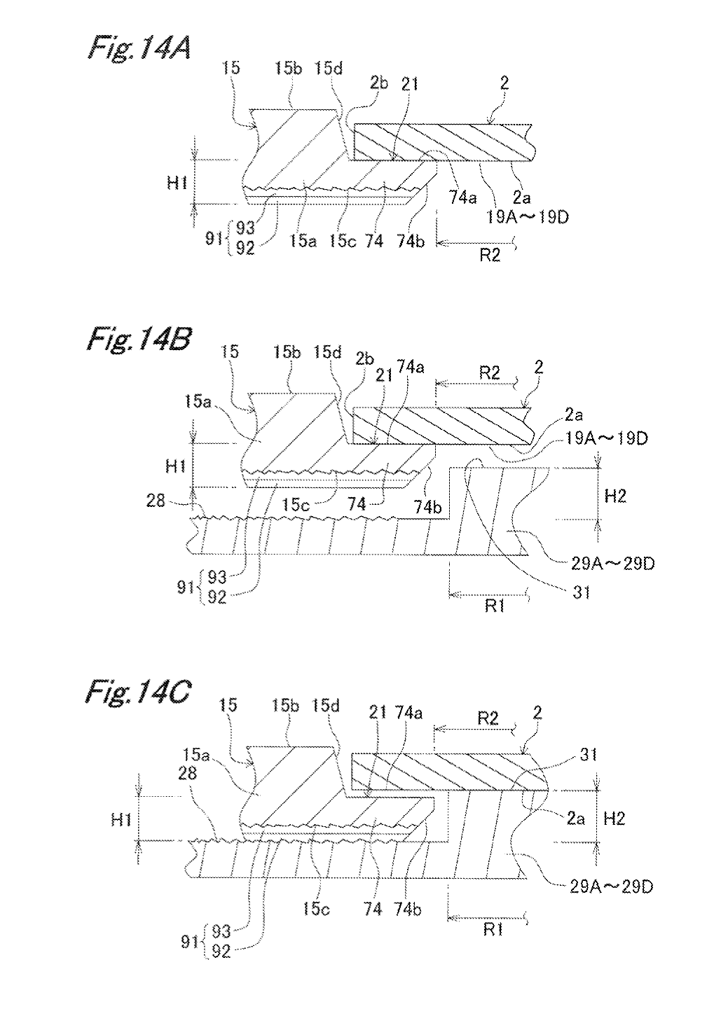

The dielectric plate 23 is cooled by heat transfer with the metal plate 24 cooled by the coolant circulation device 61. However, the tray supporting surface 28 of the dielectric plate 23 and the lower surface 15c of the tray 15 placed thereon have relatively large surface roughness, and both have concave and convex parts of about 6 μm to 10 μm (exaggeratingly shown in FIGS. 14A to 14C). In such a way, two surfaces (the tray supporting surface 28 and the lower surface 15c) having relatively large surface roughness are in contact with each other in a point contact mode when seen microscopically. Thus, a heat transfer property between the tray 15 and the dielectric plate 23 is considerably lower than the heat transfer property between the substrate 2 and the dielectric plate 23 where the electrostatic chuck is performed and the heat transfer gas is supplied. Therefore, cooling efficiency of the tray 15 is lower than the cooling efficiency of the substrate 2, and the tray 15 has a considerably higher temperature than the substrate 2 due to heat absorption from the plasma. For example, even in a case where the temperature of the substrate 2 is controlled to be about 50° C. to 100° C., the temperature of the tray 15 during etching processing is increased to about 250° C. or more.

After completion of the etching, application of the high frequency voltage from the high frequency power source 7 to the ICP coil 5 and application of the bias voltage from the high frequency application mechanism 56 to the metal plate 24 are stopped. Successively, an etching gas is exhausted from the inside of the chamber 3 by the vacuum exhaust device 13. The heat transfer gas is exhausted from the substrate placing surface 31 and the lower surface 2a of the substrate 2 by the heat transfer gas supply mechanism 45. Further, application of the DC voltage from the DC voltage application mechanism 43 to the electrostatic chuck electrode 40 is stopped, so that the electrostatic chuck of the substrate 2 is cancelled. The tray 15 and the substrate 2 are neutralized by pushing-up operation of the rising and lowering pins 18.

After neutralization, the rising and lowering pins 18 rise, and the lower surface 15c of the tray 15 is pushed up by the upper ends thereof and floated up from the tray supporting surface 28 of the dielectric plate 23. When the tray 15 further rises together with the rising and lowering pins 18, as shown in FIGS. 8B and 10B, the lower surface 2a of the substrate 2 is pushed up by the protruding sections 76A to 76C of the substrate supporting section 21 of the tray 15, and the substrate 2 is floated up from the substrate placing surface 31 in each of the substrate placing section 29A to 29D. That is, since the tray 15 rises, the substrate 2 is brought from the substrate placing sections 29A to 29D to the substrate containing holes 19A to 19D of the tray 15. The rising and lowering pins 18 rise to the rising position shown by the double chain line in FIG. 1.

After that, the tray 15 is moved to the carrying arm 16 coming from the load lock chamber 10 into the chamber 3 through the gate 3a. The tray 15 is carried out from the chamber 3 to the load lock chamber 10 by the carrying arm 16.

After the tray 15 is carried in, the load lock chamber 10 is opened to the atmosphere (a vacuum environment is switched to an atmospheric environment in the load lock chamber 10). After that, the carrying arm 16 carries out the tray 15 from the load lock chamber 10 to the alignment base 71 via the gate 10a. Finally, the carrying arm 73 puts the tray 15 on the alignment base 71 into the cassette 72B.

As described above, the tray 15 after completion of the dry etching has a considerably higher temperature than the substrate 2. When the load lock chamber 10 is opened to the atmosphere so as to make the atmospheric environment after the tray 15 is carried in, heat transfer efficiency between the tray 15 and the substrate 2 is considerably higher than the vacuum environment. However, the substrate 2 contained in each of the substrate containing holes 19A to 19D of the tray 15 is not supported in a surface contact mode relative to the substrate supporting section 21 but supported on the three protruding sections 76A to 76C of the substrate supporting section 21 in a point contact mode. That is, a contact area between the substrate 2 contained in each of the substrate containing holes 19A to 19D and the substrate supporting section 21 of the tray 15 is small. Thus, the heat transfer from the tray 15 to the substrate 2 is suppressed. Therefore, when the load lock chamber 10 in which the tray 15 is carried from the chamber 3 after the dry etching is opened to the atmosphere, a temperature increase of the substrate 2 (particularly the outer circumferential edge section) due to the heat transfer from the tray 15 can be reduced.

In such a way, with the dry etching apparatus 1 of the present embodiment, the temperature increase of the substrate 2 due to the heat transfer from the tray 15 after the dry etching can be reduced. Thus, there is no need for providing a time (stand-by time) for making the tray 15 stand-by in the chamber 3 even after the dry etching for heat release for cooling the tray 15 by the heat release, the heat transfer, or the like, so that throughput can be improved.

With a relatively simple configuration that the protruding sections 76A to 76C are provided in the substrate supporting section 21 of the tray 15 and these protruding sections 76A to 76C are only in contact with the lower surface 15c of the tray 15 in a point contact mode, reduction in the temperature increase of the substrate 2 due to the heat transfer from the tray 15 after the dry etching can be realized. Therefore, there is no need for providing a cooling chamber for cooling the tray 15 after the dry etching in vacuum outside the chamber 3 in order to cool the tray 15. In this point, simplification of the apparatus and cost reduction can be realized.

When the tray 15 is repeatedly used for the dry etching of the substrate 2, chipping caused by performing the etching to the tray 15 itself progresses as shown by a double chain line in FIG. 8C. In a case where size of a gap between the end surface 2h of the substrate 2 and the hole wall 15b of the tray 15 is large, particularly, the chipping remarkably progresses in a connection part between the hole wall 15d in each of the substrate containing holes 19A to 19D and the upper surface 74a of the annular section 74 as shown by a reference sign A in FIG. 8C. However, in the present embodiment, the substrate 2 contained in each of the substrate containing holes 19A to 19D is not supported on the tray 15 at the part A where the chipping remarkably progresses but the substrate 2 is supported on the upper surfaces 76a of the protruding sections 76A to 76C of the tray 15. Therefore, an influence of progress of the chipping of the tray 15 itself over support precision of the substrate 2 is small, and the lifetime of the tray 15 is long.

### Second Embodiment

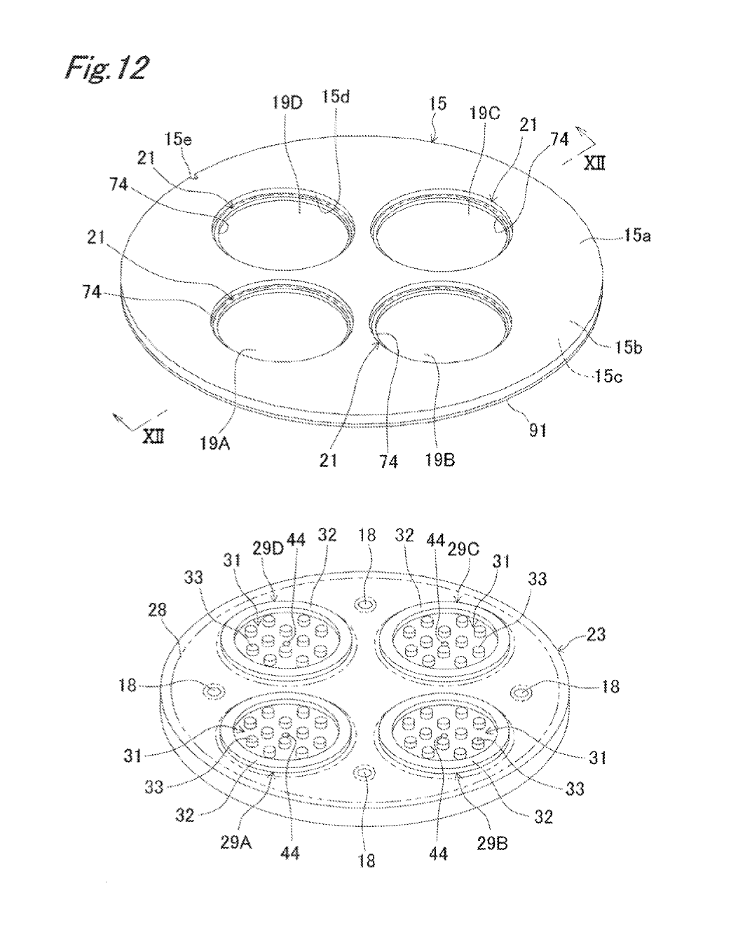

In a second embodiment of the present invention shown in FIGS. 11 to 15C, instead of providing the protruding sections 76A to 76C for supporting the lower surface 2a of the substrate 2 on the tray 15 in a point contact mode, a polyimide tape 91 is attached to the lower surface 15c of the tray 15. The polyimide tape 91 is attached by one of or both vacuum adhesion and thermocompression bonding. The polyimide tape 91 is provided with a tape base material (heat transfer material layer) 92 made of polyimide, and an adhesive layer 93 formed on one surface of this tape base material 92. In a case of the thermocompression bonding, the adhesive layer 93 is not necessarily provided. Thereby, there are not such problems that the adhesive layer is exfoliated from an edge of the lower surface 15c of the tray 15 to which the polyimide tape 91 is thermocompression bonded in a case where the apparatus is used for a long time. The adhesive layer 93 is put between the lower surface 15c of the tray 15 and the tape base material 92. In a case of attachment by the vacuum adhesion, there are no bubbles and the like between the polyimide tape 91 and the lower surface 15c of the tray 15, and thus a degree of close attachment between the both is high. Therefore, a heat transfer property between the tray 15 and the polyimide tape 91 is favorable. In FIG. 12, as shown by a double chain line, the polyimide tape 91 is formed into a discoid shape in which openings are formed in the substrate placing sections 29A to 29D of the dielectric plate 23 and at protruding positions of the rising and lowering pins 18.

Polyimide is suitable as a material of the tape base material 92 in terms of favorable heat-resistant, insulating, flexible, plasma-resistant, and Cl-resistant properties. Other resin materials in which these properties are favorable may be adopted as the material of the tape base material 92. For example, polytetrafluoroethylene (Teflon (trademark)) is also suitable as the material of the tape base material 92 due to the heat-resistant and insulating properties thereof. Instead of the vacuum adhesion of a resin tape such as the polyimide tape 91, a layer of a resin material having the above properties may be directly formed on the lower surface 15c of the tray 15 by thermal spraying or the like. Thickness of the tape base material 92 is about 20 μm to 50 μm.

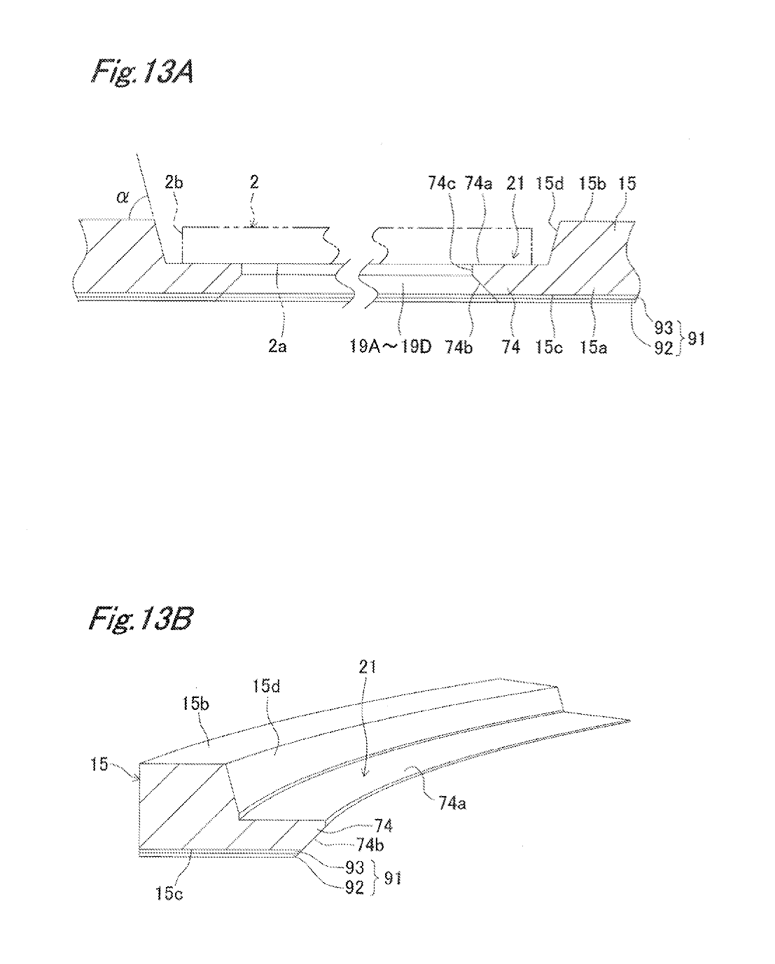

As most clearly shown in FIG. 13B, the substrate supporting section 21 is not provided with the protruding sections 76A to 76C (refer to FIG. 7C). As most clearly shown in FIGS. 13A, 14A, and 14B, the lower surface 2a of the outer circumferential edge section of the substrate 2 contained in each of the substrate containing holes 19A to 19D is placed and thus supported on the upper surface 74a of the annular section 74.

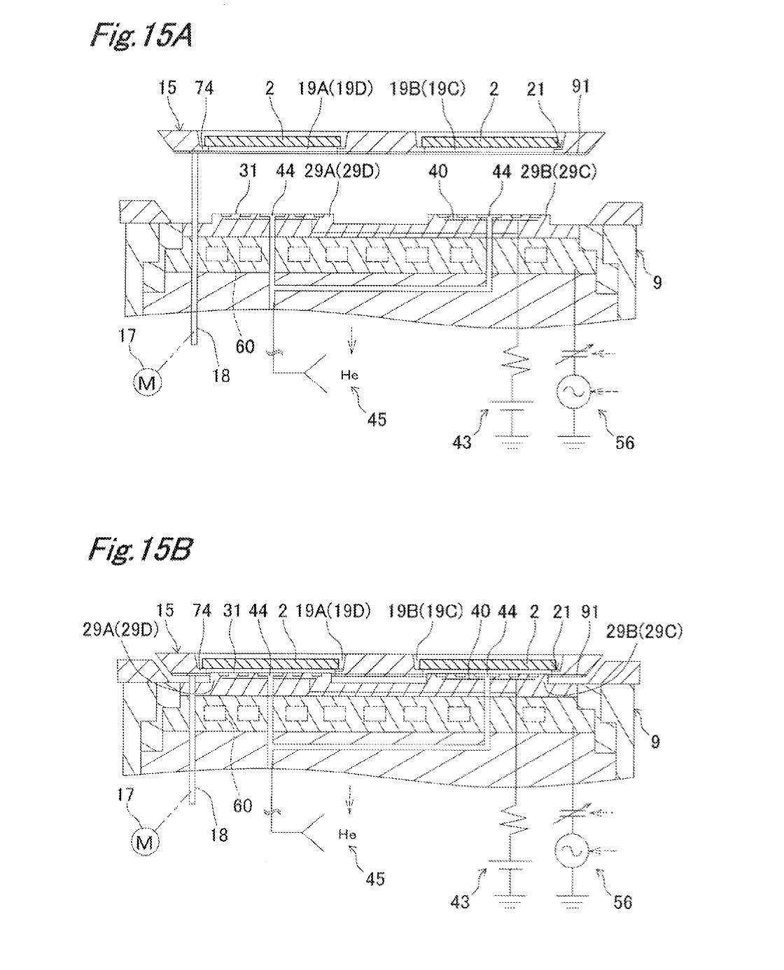

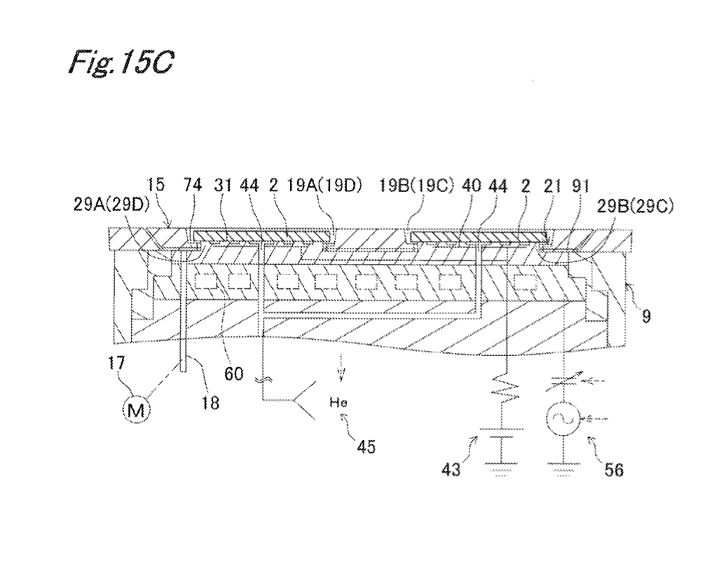

The tray 15 containing the substrate 2 carried from the load lock chamber 10 into the chamber 3 is supported on the upper ends of the rising and lowering pins 18 as shown in FIG. 15A, and lowered toward the substrate susceptor 9 in accordance with lowering of the rising and lowering pins 18. With reference to FIGS. 14B, 14C, 15B, and 15C, the tray 15 is lowered until the lower surface 15c to which the polyimide tape 91 is attached is placed onto the tray supporting surface 28 of the dielectric plate 23, and the tray 15 is supported on the tray supporting surface 28 via the polyimide tape 91. In this state, the substrate 2 is separated from the upper surface 74a of the annular section 74 in the substrate supporting section 21 of the tray 15 by a predetermined amount, and brought to and supported on the substrate placing surface 31 in each of the substrate placing sections 29A to 29D.

By applying the DC voltage from the DC voltage application mechanism 43 to the electrostatic chuck electrode 40, the substrate 2 is electrostatically attracted to the substrate placing surface 31. When the plasma is generated and the bias voltage is applied to the metal plate 24 of the substrate susceptor 9, a negative sheath potential is generated on the tray 15 with the lower surface 15c supported on the tray supporting surface 28 of the dielectric plate 23 of the substrate susceptor 9 and a potential in the polyimide tape 91 (tape base material 92 made of polyimide) having the insulating property is polarized. As a result, the tray 15 electrostatically attracts itself onto the tray supporting surface 28 of the dielectric member 23. The lower surface 15c of the tray 15 is pushed onto the tray supporting surface 28 by electrostatically attracting itself.

As exaggeratingly shown in FIGS. 14A to 14C, the tray supporting surface 28 of the dielectric plate 23 has relatively large surface roughness, and has concave and convex parts of about 6 μm to 10 μm. However, the polyimide tape 91 having a considerably higher flexible property than a material of the tray 15 such as alumina is attached to the lower surface 15c of the tray 15 by the vacuum adhesion. Therefore, the lower surface 15c of the tray 15 pushed by electrostatically attracting itself is closely attached to the tray supporting surface 28 having the concave and convex parts by deforming the polyimide tape 91 (particularly the tape base material 92). That is, since the polyimide tape 91 is put inbetween, the lower surface 15c of the tray 151s not in contact with the tray supporting surface 28 in a point contact mode but a contact area with the tray supporting surface 28 is large and a degree of close attachment is high. Therefore, the heat transfer property between the tray 15 and the dielectric plate 23 is favorable. Since the polyimide tape 91 is attached by the vacuum adhesion as described above, a heat transfer property with the tray 15 is also favorable. In such a way, the heat transfer property between the tray 15 and the polyimide tape 91 and the heat transfer property between the polyimide tape 91 and the dielectric plate 23 (tray supporting surface 28) are both favorable. As a result, heat absorbed by the tray 15 from the plasma during the dry etching is transmitted to the dielectric plate 23 (cooled by the heat transfer with the metal plate 24 cooled by the coolant circulation device 61) via the polyimide tape 91 at favorable heat transfer efficiency, so that the tray 15 is effectively cooled. For example, in a case where the temperature of the substrate 2 is controlled to be about 50° C. to 100° C., a temperature increase of the tray 15 upon completion of the etching is reduced by effective cooling, so that the temperature of the tray 15 is about 150° C. to 200° C. If the tray 15 is placed on the dielectric plate 23 without putting the polyimide tape 91 inbetween, the temperature of the tray 15 during the etching processing is increased to about 250° C. or more.

After the completion of the etching, the tray 15 is carried to the load lock chamber 10, and further, the load lock chamber 10 is opened to the atmosphere. By this opening to the atmosphere, the heat transfer efficiency between the tray 15 and the substrate 2 is considerably increased. However, since the temperature increase of the tray 15 itself during the dry etching is suppressed, the temperature increase of the substrate 2 (particularly the outer circumferential edge section) due to the heat transfer from the tray 15 after the opening to the atmosphere can be reduced.

In such a way, with the dry etching apparatus 1 of the present embodiment, the temperature increase of the substrate 2 due to the heat transfer from the tray 15 after the dry etching can be reduced. Thus, there is no need for providing the stand-by time of the tray 15 after the dry etching for cooling the tray 15 by the heat release, the heat transfer, or the like, so that the throughput can be improved.

With a relatively simple configuration that the polyimide tape 91 is attached to the lower surface 15c of the tray 15 by the vacuum adhesion, the reduction in the temperature increase of the substrate 2 due to the heat transfer from the tray 15 after the dry etching can be realized, and there is no need for providing a cooling chamber for cooling the tray 15 after the dry etching in vacuum outside the chamber 3 in order to cool the tray 15. In this point, the simplification of the apparatus and the cost reduction can be realized.

In a case where one tray 15 is repeatedly used for the etching processing, a cycle of the temperature increase and a temperature decrease due to the etching processing is repeated in the tray 15. However, the tray 15 itself is cooled in the present embodiment. Thus, even in a case where one tray 15 is repeatedly used for the etching, a temperature difference (absolute value) generated by the cycle of the temperature increase and decrease can be smaller. As a result, even in a case where the tray 15 is used for a long time and the etching processing is repeated, deflection and damage of the tray 15 caused by repeating the cycle of the temperature increase and decrease are not easily generated. Since the tray 15 itself is cooled, the progress of the chipping of the tray 15 due to the etching can be suppressed. In these points, there is an effect of extending the lifetime of the tray 15.

Since other configurations and operations of the second embodiment are similar to the first embodiment, the same elements are given the same reference signs, and description thereof is omitted.

### Third Embodiment

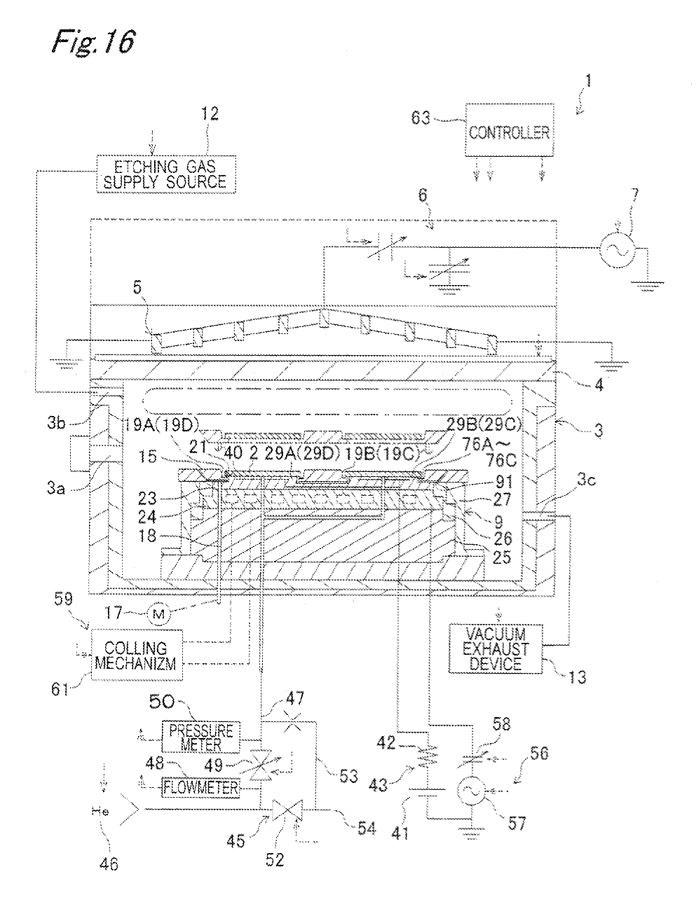

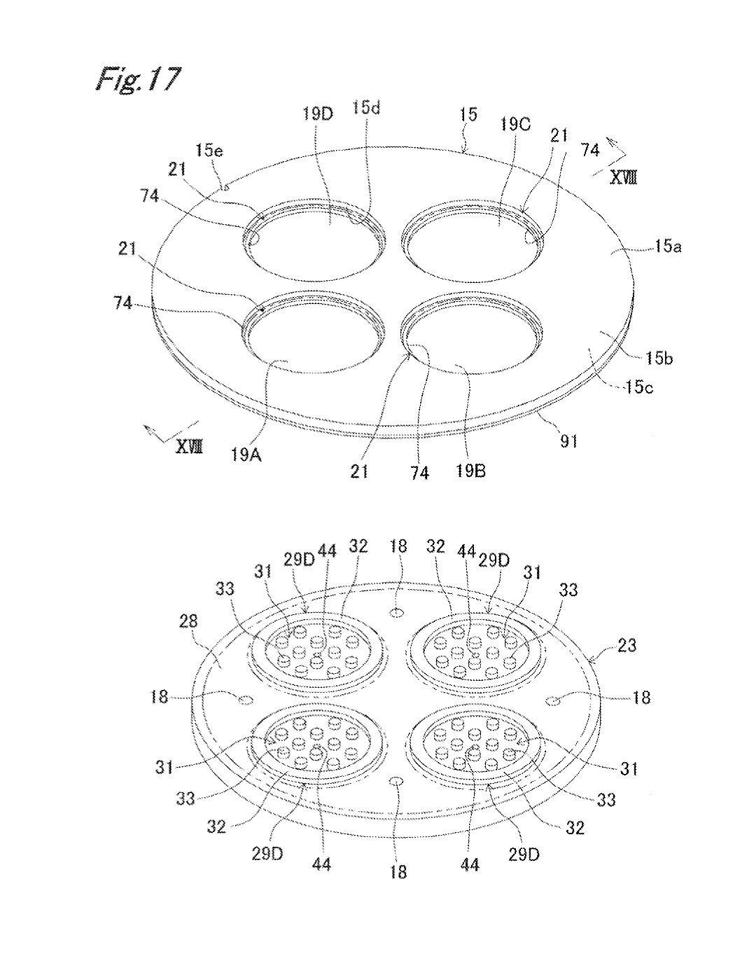

In a third embodiment shown in FIGS. 16 to 20C, support of the substrate 2 on the tray 15 in a point contact mode of the first embodiment (protruding sections 76A to 76C) and the polyimide tape 91 of the second embodiment are both adopted.

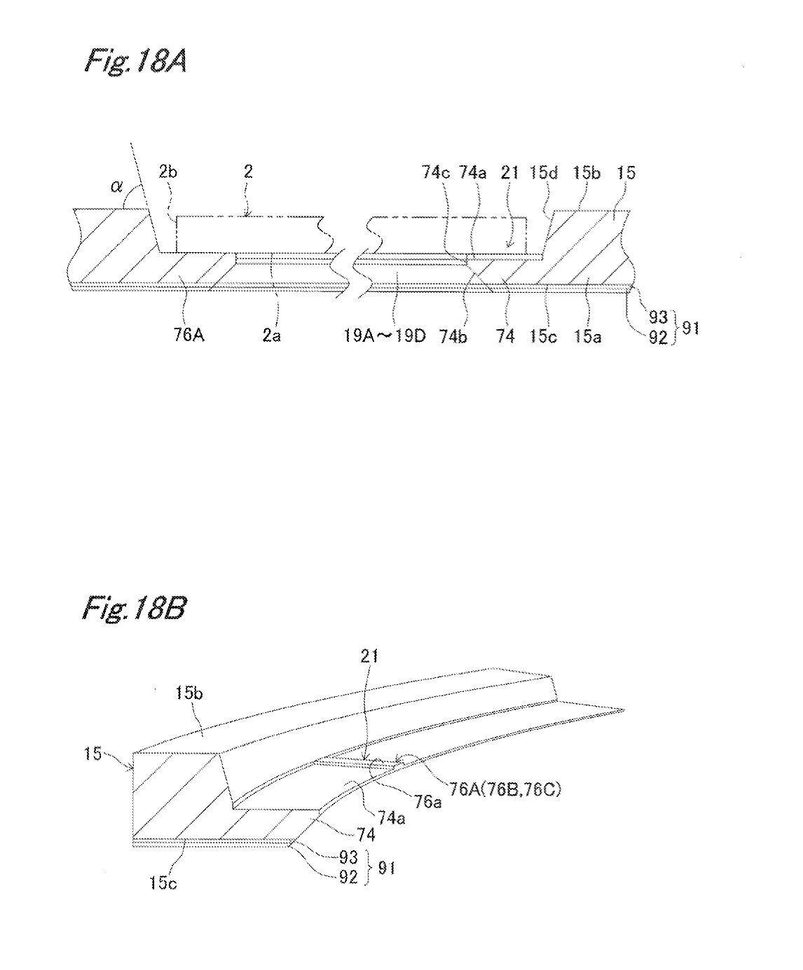

As most clearly shown in FIG. 18B, in the substrate supporting section 21, the protruding sections 76A to 76C are provided on the upper surface 74a of the annular section 74 (provided on the entire circumference of the hole wall 15d) protruding from the side of the lower surface 15c of the tray 15 in the hole wall 15d in each of the substrate containing holes 19A to 19D so as to be spaced from each other at regular angles. These protruding sections 76A to 76C extend over the entire width of the annular section 74, and the upper surfaces 76a are flat surfaces extending in the horizontal direction. The lower surface 2a of the outer circumferential edge section of the substrate 2 contained in each of the substrate containing holes 19A to 19D is placed on the upper surfaces 76a of the protruding sections 76A to 76C, so that the substrate is supported on the substrate supporting section 21 supporting the substrate 2 in a point contact mode (three-point support).

The polyimide tape 91 provided with the tape base material (heat transfer material layer) 92 made of polyimide, and the adhesive layer 93 formed on one surface of this tape base material 92 is attached to the lower surface 15c of the tray 15 by the vacuum adhesion or the thermocompression bonding.

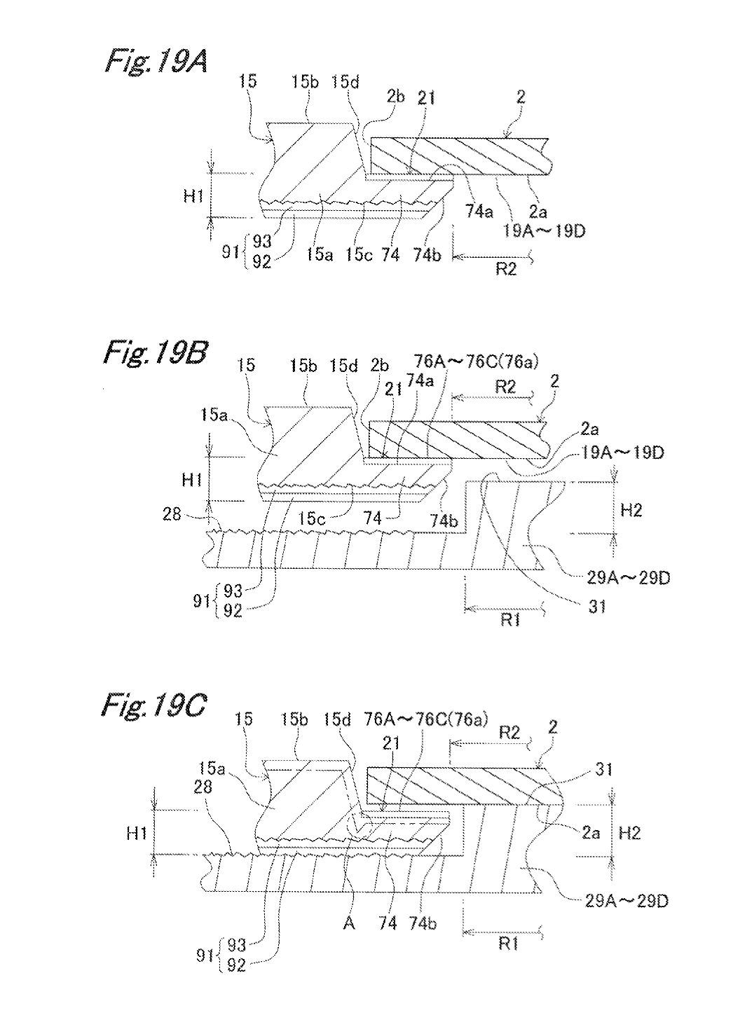

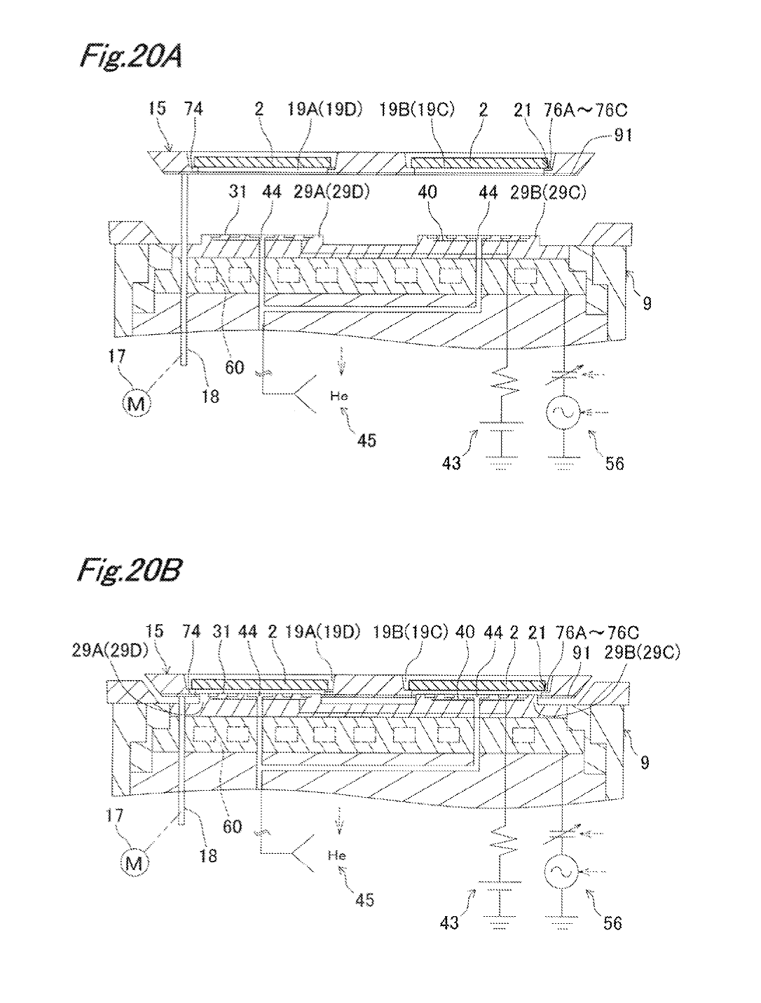

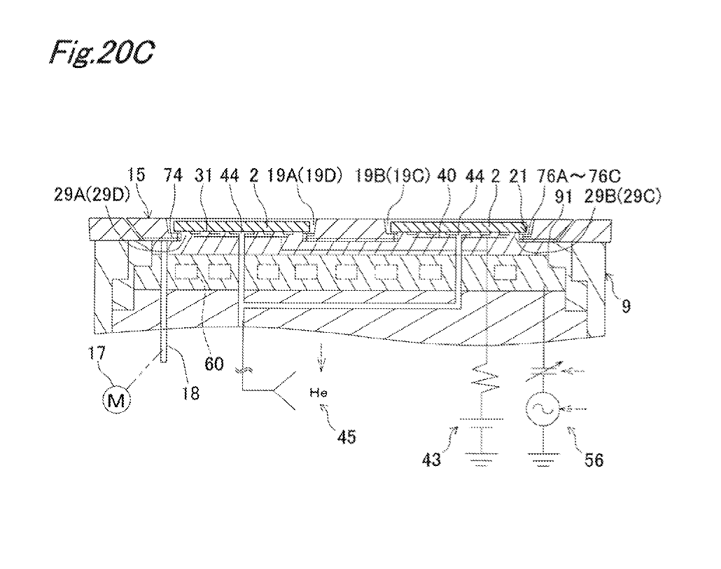

The tray 15 containing the substrate 2 carried from the load lock chamber 10 into the chamber 3 is supported on the upper ends of the rising and lowering pins 18 as shown in FIG. 20A, and lowered toward the substrate susceptor 9 in accordance with the lowering of the rising and lowering pins 18. With reference to FIGS. 19B, 19C, 20B, and 20C, the lower surface 15c of the tray 15 to which the polyimide tape 91 is attached is lowered to the tray supporting surface 28 of the dielectric plate 23 of the substrate susceptor 9, and the tray 15 is supported on the tray supporting surface 28 via the polyimide tape 91. In this state, the substrate 2 is separated from the protruding sections 76A to 76C of the upper surfaces 76a of the annular section 74 in the substrate supporting section 21 of the tray 15 by a predetermined amount, and brought to and supported on the substrate placing surface 31 in each of the substrate placing sections 29A to 29D.

By applying the DC voltage from the DC voltage application mechanism 43 to the electrostatic chuck electrode 40, the substrate 2 is electrostatically attracted to the substrate placing surface 31. When the plasma is generated and the bias voltage is applied to the metal plate 24 of the substrate susceptor 9, a negative sheath potential is generated on the tray 15 with the lower surface 15c supported on the tray supporting surface 28 of the dielectric plate 23 of the substrate susceptor 9 and the potential in the polyimide tape 91 (tape base material 92 made of polyimide) having the insulating property is polarized. As a result, the tray 15 electrostatically attracts itself onto the tray supporting surface 28 of the dielectric member 23. The lower surface 15c of the tray 15 is pushed onto the tray supporting surface 28 by electrostatically attracting itself.

As exaggeratingly shown in FIGS. 19A to 19C, the tray supporting surface 28 of the dielectric plate 23 has relatively large surface roughness, and has the concave and convex parts of about 6 μm to 10 μm. However, the lower surface 15c of the tray 15 pushed by electrostatically attracting itself is closely attached to the tray supporting surface 28 having the concave and convex parts by deforming the polyimide tape 91 (particularly the tape base material 92) having a high flexible property. Therefore, the heat transfer property between the tray 15 and the dielectric plate 23 is favorable. Since the polyimide tape 91 is attached by the vacuum adhesion, the heat transfer property with the tray 15 is also favorable. In such a way, the heat transfer property between the tray 15 and the polyimide tape 91 and the heat transfer property between the polyimide tape 91 and the dielectric plate 23 (tray supporting surface 28) are both favorable. Thus, the heat absorbed by the tray 15 from the plasma during the dry etching is transmitted to the dielectric plate 23 via the polyimide tape 91 at favorable heat transfer efficiency. As a result, the tray 15 during the dry etching is effectively cooled. For example, in a case where the temperature of the substrate 2 is controlled to be about 50° C. to 100° C., the temperature increase of the tray 15 during the etching processing is reduced by effective cooling, so that the temperature of the tray is about 150° C. to 200° C. If the tray 15 is placed on the dielectric plate 23 without putting the polyimide tape 91 inbetween, the temperature of the tray 15 during the etching processing is increased to about 250° C. or more.

After the completion of the etching, the tray 15 is carried to the load lock chamber 10, and further, the load lock chamber 10 is opened to the atmosphere. By this opening to the atmosphere, the heat transfer efficiency between the tray 15 and the substrate 2 is considerably increased. However, due to a synergetic effect of the following two points, the temperature increase of the substrate 2 (particularly the outer circumferential edge section) due to the heat transfer from the tray 15 after the opening to the atmosphere can be reduced.

Firstly, the substrate 2 contained in each of the substrate containing holes 19A to 19D of the tray 15 is not supported in a surface contact mode relative to the substrate supporting section 21 but supported on the three protruding sections 76A to 76B of the substrate supporting section 21 in a point contact mode. That is, the contact area between the substrate 2 contained in each of the substrate containing holes 19A to 19D and the substrate supporting section 21 of the tray 15 is small. Thus, the heat transfer from the tray 15 to the substrate 2 after the opening to the atmosphere is suppressed.

Since the polyimide tape 91 is attached to the lower surface 15c, the tray 15 is effectively cooled during the dry etching and the temperature increase of the tray 15 itself is suppressed. Thus, the temperature increase of the substrate 2 (particularly the outer circumferential edge section) due to the heat transfer from the tray 15 after the opening to the atmosphere can be reduced.

Further, since the tray 15 itself is cooled, the deflection and the damage of the tray 15 caused by repeating the cycle of the temperature increase and decrease are not easily generated, and the progress of the chipping of the tray 15 due to the etching can be suppressed. Thus, there is an effect of extending the lifetime of the tray 15.

Since other configurations and operations of the third embodiment are similar to the first embodiment, the same elements are given the same reference signs, and description thereof is omitted.

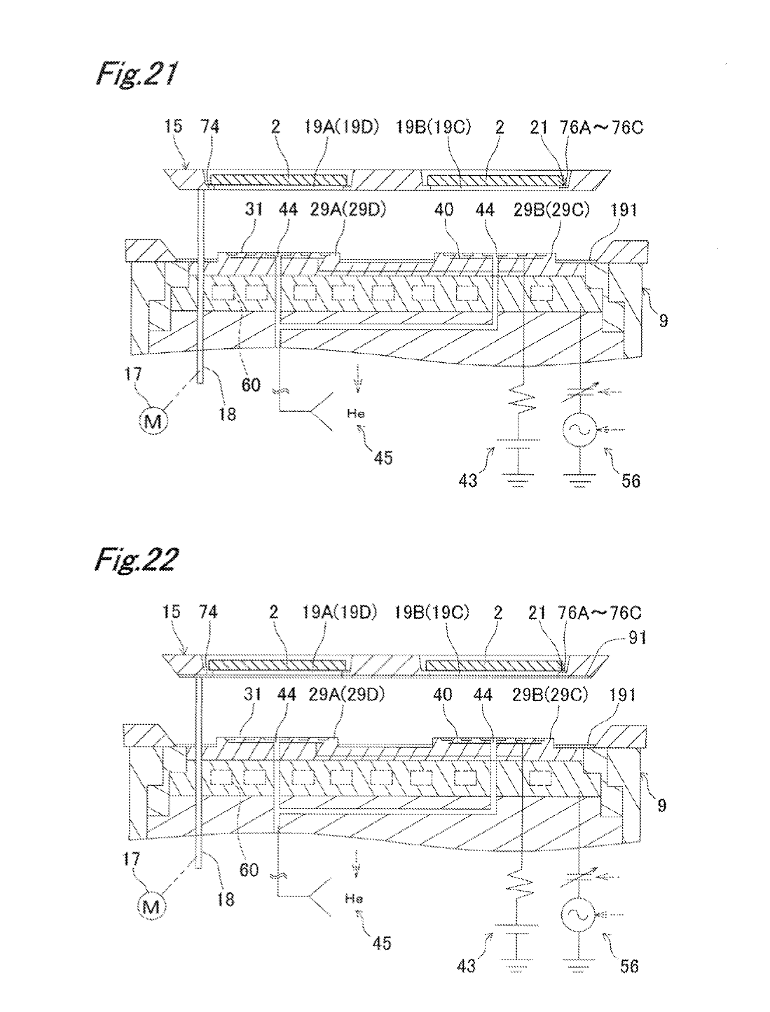

FIGS. 21 and 22 show alternatives relating to the polyimide tape serving as the heat transfer material layer. In an example of FIG. 21, the polyimide tape is not attached to the lower surface of the tray 15. However, a polyimide tape 191 is attached to the tray supporting surface 28 of the dielectric plate 23 by the vacuum adhesion or the thermocompression bonding. In this case, since the polyimide tape is not attached, unit cost of the tray 15 is reduced. Particularly in a case where a large number of trays 15 are used, an effect of reducing the cost can be expected. In an example of FIG. 22, the polyimide tapes 91, 191 are attached to both the lower surface of the tray 15 and the tray supporting surface 28 of the dielectric plate 23 by the vacuum adhesion or the thermocompression bonding. In this case, since an adhesion property between the lower surface of the tray 15 and the tray supporting surface 28 is improved, more effective cooling of the tray 15 due to further improvement of the heat transfer property between the tray 15 and the dielectric plate 23 can be expected. Meanwhile, in a case where the polyimide tape 91 is attached only to the lower surface of the tray 15 as in the second embodiment, that is, in a case where the polyimide tape 191 is not attached to the tray supporting surface 28, there is an effect that maintenance is easily performed. Hereinafter, this point will be described. The polyimide tape 191 attached on the side of the dielectric plate 23 as in FIGS. 21 and 22 is exposed to the plasma for a long time. Thus, exfoliation, degradation, or the like is caused even by a tiny amount of plasma invading from the side of an end in a part where the lower surface of the tray 15 is placed on and closely attached to the tray supporting surface 28. The exfoliation, the degradation, or the like of this polyimide tape 191 lead to problems such as deterioration of the adhesion property between the tray 15 and the tray supporting surface 28 and generation of particles. In order to prevent this, regular maintenance is performed to the dielectric plate 23. Thus, there is a need for replacing the polyimide tape 191 attached to the tray supporting surface 28 of the dielectric plate 23 with a new polyimide tape, and there is a need for stopping facilities in accordance with this maintenance. The replacement of the polyimide tape 191 attached to the tray supporting surface 28 requires a complicated task. Meanwhile, in a case where the polyimide tape 91 is attached only to the lower surface of the tray 15 as in the second embodiment, there is no need for performing the replacement of the polyimide tape on the side of the dielectric plate 23, which is the complicated task, and the number of the maintenance is reduced.

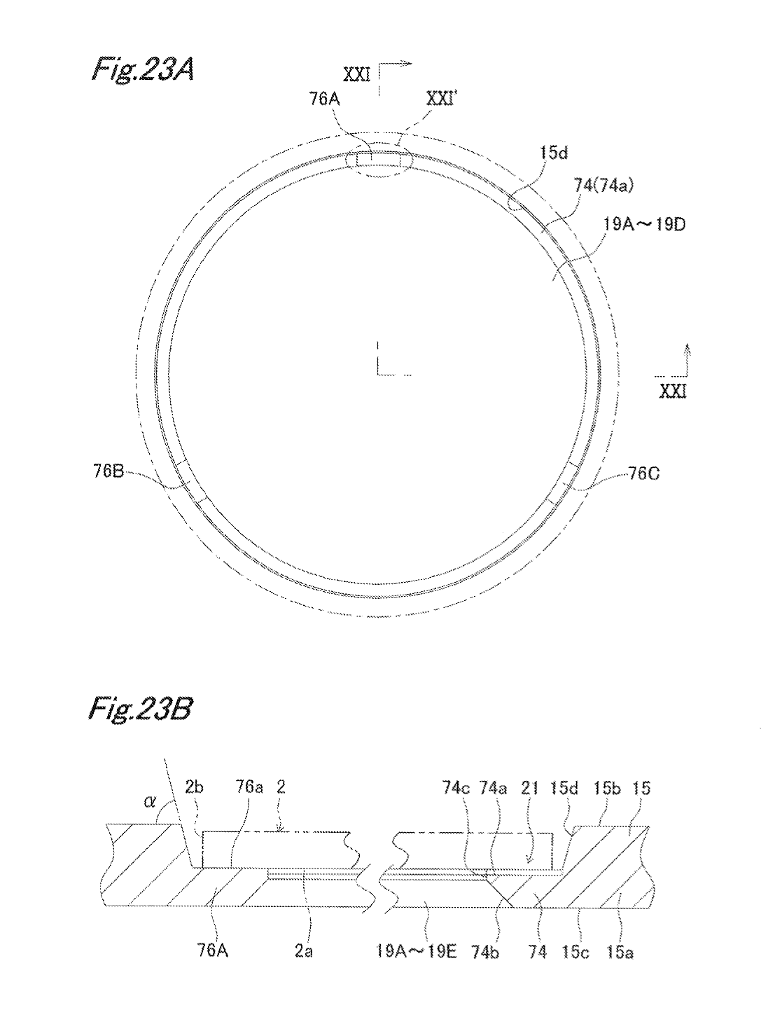

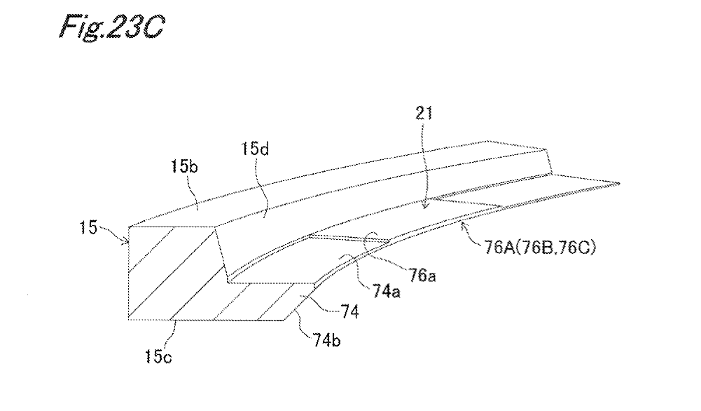

FIGS. 23A to 26C show various structures to be adopted as the substrate supporting section 21 of the tray 15. These structures can be adopted both in a case where the polyimide tape 91 is not attached to the lower surface 15c of the tray 15 as in the first embodiment and in a case where the polyimide tape 91 is attached to the lower surface 15c of the tray 15 as in the third embodiment.

In an example shown in FIGS. 23A to 23C, the protruding sections 76A to 76C are provided on the upper surface 74a of the annular section 74. However, width of these protruding sections 76A to 76C is set to be larger than the first and third embodiments.

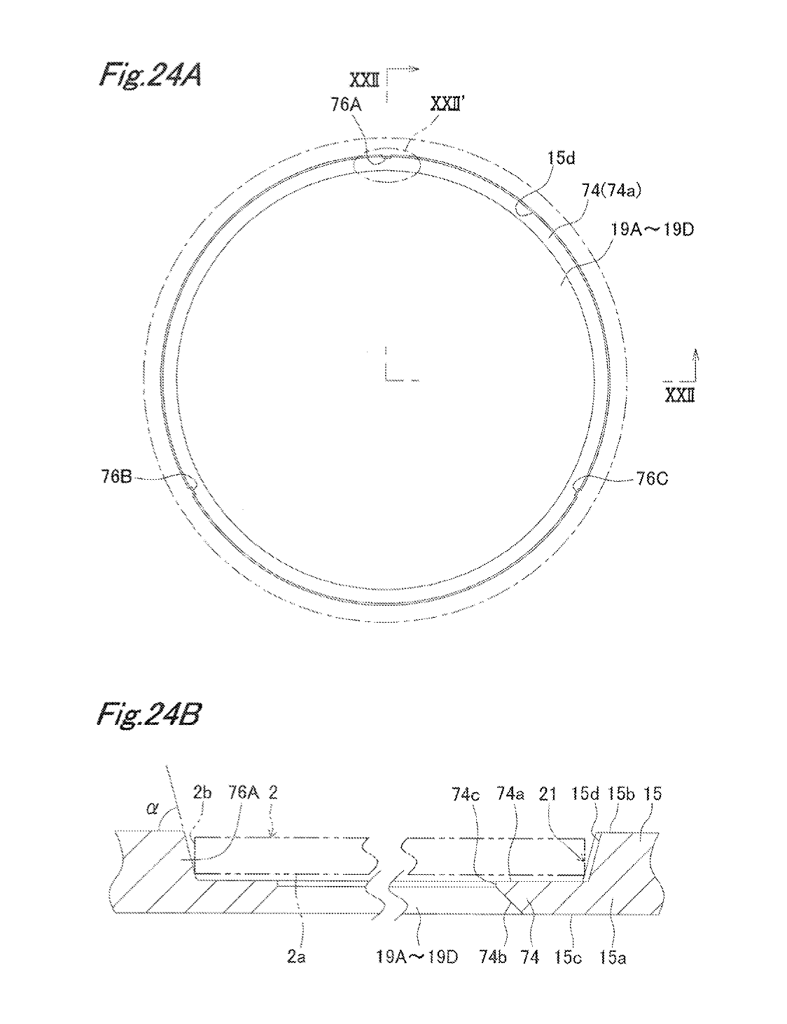

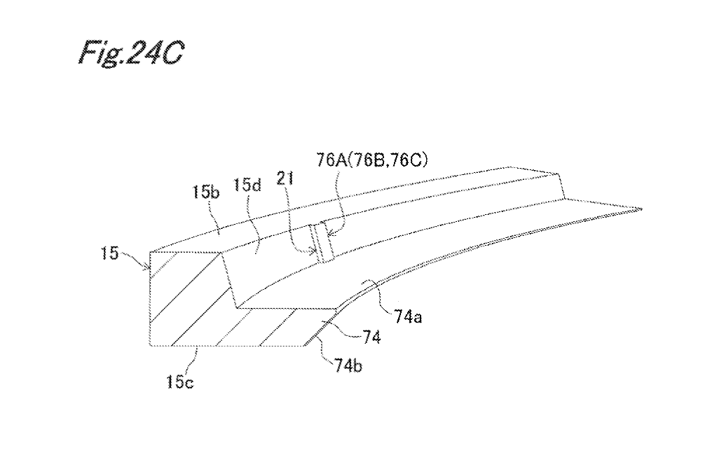

In an example shown in FIGS. 24A to 24C, the protruding sections 76A to 76C protruding from the hole wall 15d are provided so as to be spaced from each other at regular angles. Specifically, the protruding sections 76A to 76C extend from a connection position between the upper surface 15b of the tray 15 and the hole wall 15d to the connection position between the hole wall 15d and the upper surface 74a of the annular section 74. The upper surfaces 76a of the protruding sections 76A to 76C are flat surfaces extending along the hole wall 15d, the flat surfaces being inclined relative to the horizontal direction as well as the hole wall 15d.

When the substrate 2 is brought into each of the substrate containing holes 19A to 19D from the side of the upper surface 15b of the tray 15, the outer circumferential edge section of the substrate 2 (more specifically, the edge of the connection part between the lower surface 2a and the end surface 2h) is guided and lowered by the upper surfaces 76a of the protruding sections 76A to 76C. Therefore, when the substrate 2 is brought into each of the substrate containing holes 19A to 19D, the hole wall 15d in each of the substrate containing holes 19A to 19D is not in contact with the edge of the substrate 2. As shown in FIG. 24B, the edge of the connection part between the lower surface 2a and the end surface 2b is supported on the upper surfaces 76a on the side of lower ends of the protruding sections 76A to 76C (positions close to the upper surface 74a of the annular section 74). Therefore, irrespective of having a warp, three points of the outer circumferential edge section of the substrate 2 are supported on the protruding sections 76A to 76C of the substrate supporting section 21 in a point contact mode (three-point support).

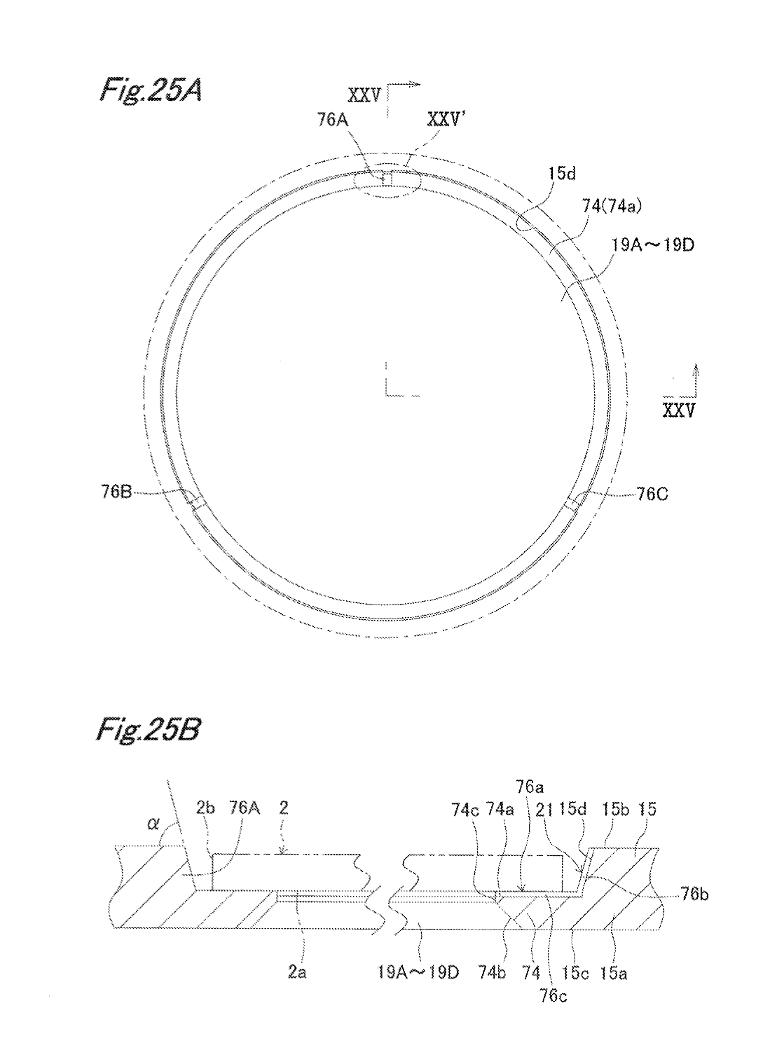

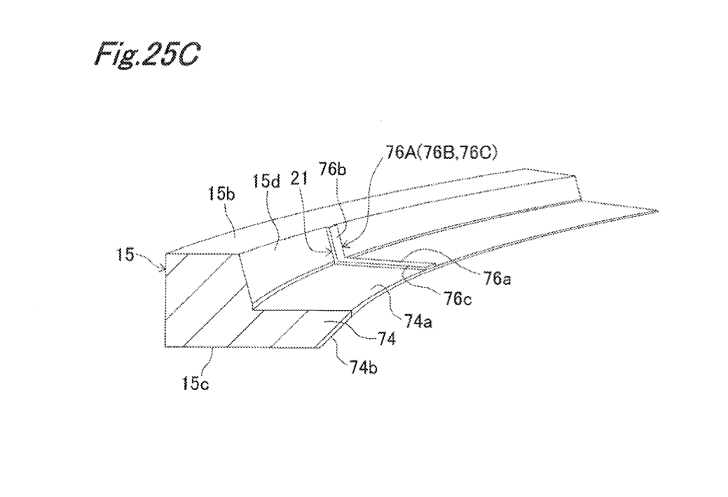

In an example shown in FIGS. 25A to 25C, the protruding sections 76A to 76C extending over both the hole wall 15d and the upper surface 74a of the annular section 74 are provided so as to be spaced from each other at regular angles. Specifically, each of the protruding sections 76A to 76C is provided with an upper part 76b protruding from the hole wail 15d, and a lower part 76c protruding from the upper surface 74a of the annular section 74 continuously to this upper part 76b. The upper surfaces 76a in the upper parts 76b of the protruding sections 76A to 76C are flat surfaces inclined along the hole wall 15d, and the upper surfaces 76a in the lower parts 76c are flat surfaces extending in the horizontal direction.

When the substrate 2 is brought into each of the substrate containing holes 19A to 19D from the side of the upper surface 15b of the tray 15, the outer circumferential edge section of the substrate 2 (more specifically, the edge of the connection part between the lower surface 2a and the end surface 2b) is guided and lowered by the upper surfaces 76a in the upper parts 76b of the protruding sections 76A to 76C. Therefore, when the substrate 2 is brought into each of the substrate containing holes 19A to 19D, the hole wall 15d in each of the substrate containing holes 19A to 19D is not in contact with the edge of the substrate 2. As shown in FIG. 25B, the lower surface 2a of the outer circumferential edge section of the substrate 2 is supported on the upper surfaces 76a in the lower parts 76c of the protruding sections 76A to 76C. Therefore, irrespective of having the warp, the three points of the outer circumferential edge section of the substrate 2 are supported on the protruding sections 76A to 76C of the substrate supporting section 21 in a point contact mode (three-point support).

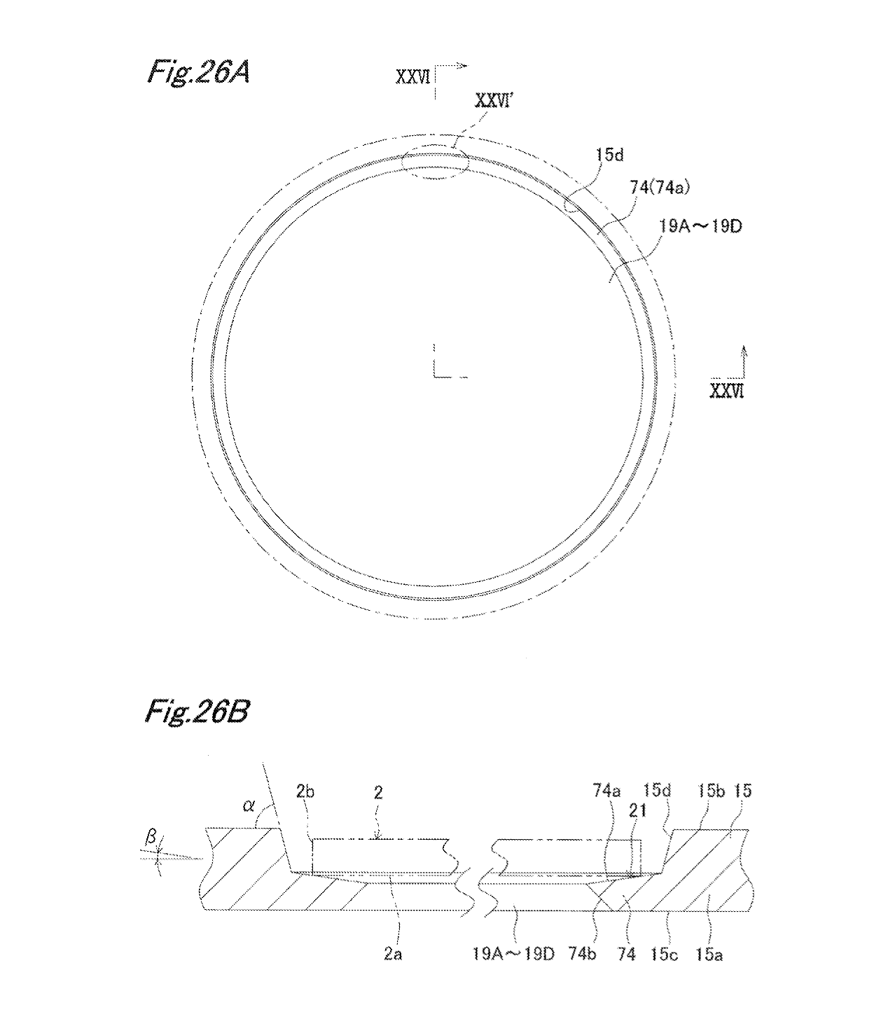

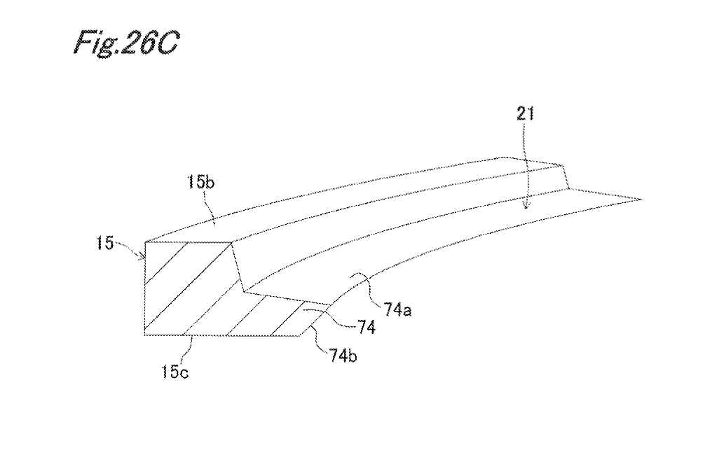

In an example shown in FIGS. 26A to 26C, the upper surface 74a of the annular section 74 functions as a substrate contact section. The upper surface 74a of the annular section 74 is inclined relative to the horizontal direction by an inclination angle β which is smaller than the hole wall 15d toward center of the substrate containing holes 19A to 19D. The inclination angle β is sufficiently smaller than the inclination angle α, and set to be less than 45°. For example, in a case where the inclination angle α of the hole wall 15d is 75°, the inclination angle β of the upper surface 74a of the annular section 74 is set to be about 8°.

When the substrate 2 is brought into each of the substrate containing holes 19A to 19D from the side of the upper surface 15b of the tray 15, the outer circumferential edge section of the substrate 2 (more specifically, the edge of the connection part between the lower surface 2a and the end surface 2b) is guided and lowered by the hole wall 15d in each of the substrate containing holes 19A to 19D. As shown in FIG. 26B, the edge of the substrate 2 is in contact with the upper surface 74a of the annular section 74, and thereby, the substrate 2 is supported. Therefore, in a case where the substrate 2 has a non-axisymmetric warp, the outer circumferential edge section of the substrate 2 is supported on the substrate supporting section 21 in a point contact mode (plural-point support). Meanwhile, in a case where the substrate 2 has an axisymmetric warp or in a case where the substrate 2 has no warp, the entire circumference of the outer circumferential edge section (entire circumference of the edge) is supported on the substrate supporting section 21. Even in a case where the substrate 2 is supported on the substrate supporting section 21 in a line contact mode, the contact area between the substrate 2 and the tray 15 is smaller than support in a surface contact mode. Therefore, even in this case, when the load lock chamber 10 in which the tray 15 is carried from the chamber 3 after the dry etching is opened to the atmosphere, the heat transfer from the tray 15 to the substrate 2 is suppressed, so that the temperature increase of the substrate 2 (particularly the outer circumferential edge section) can be reduced.

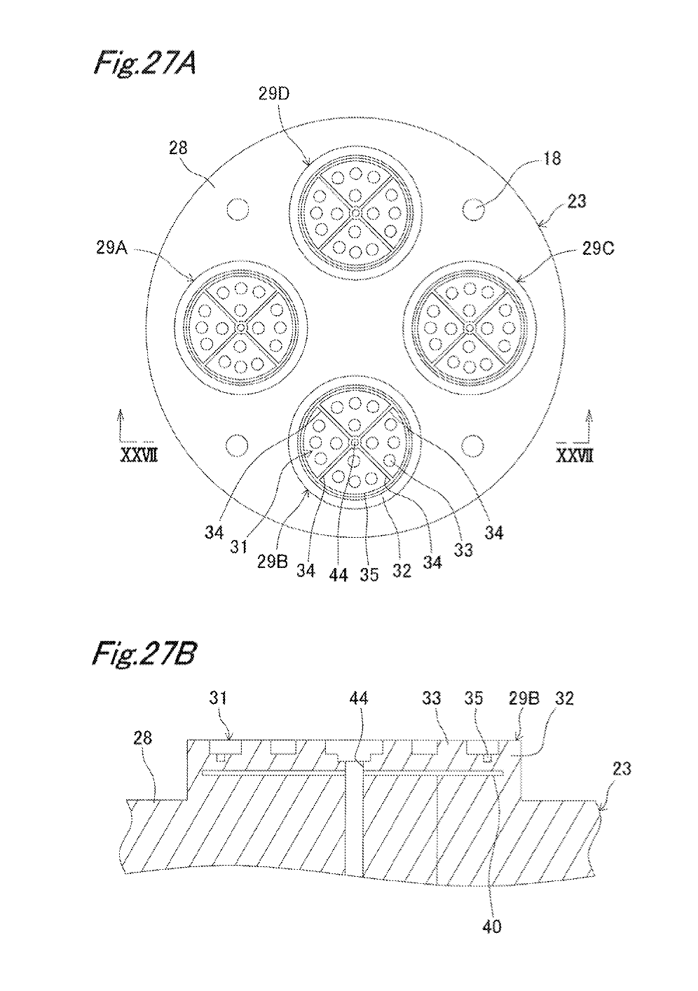

FIGS. 27A and 27B show an alternative of the dielectric plate 23. This alternative can be applied to all the first to third embodiments. Four straight grooves 34 extending from the supply hole 44 in a radial manner and a ring shape groove 35 arranged on the inner side of the ring shape projecting section 32 are provided in the substrate placing surface 31. The straight grooves 34 and the ring shape groove 35 communicate with each other. By providing these straight grooves 34 and the ring shape groove 35, the heat transfer gas jetted from the supply hole 44 is uniformly diffused into the space between the lower surface 2a of the substrate 2 and the substrate placing surface 31. As a result, the cooling efficiency of the substrate 2 and the precision of the temperature control can be further improved.

### Experimental Example

Experiments for confirming an effect of reducing the temperature increase of the substrate according to the present invention were performed. Specifically, the dry etching processing is executed with using a conventional tray and the tray 15 according to the present invention, and the temperatures of the substrate 2 and the tray 15 were measured during the dry etching, and before carrying-out to the load lock chamber 10 and opening of the load lock chamber to the atmosphere and after the opening of the load lock chamber 10 to the atmosphere after the etching. Further in detail, temperature measurement was executed for three comparative examples 1 to 3 corresponding to conventional examples and two experimental examples 1, 2 corresponding to the embodiments of the present invention.

In the comparative examples 1 to 3, the tray 15 of the second embodiment (FIGS. 12 to 13B) in which the polyimide tape 91 is removed from the lower surface 15c was used. That is, the comparative examples 1 to 3 are examples in which the lower surface 2a of the outer circumferential edge section of the substrate 2 is supported on the upper surface 74a of the annular section 74 in a surface contact mode, and the cooling of the tray 15 itself by providing the polyimide tape 91 is not executed. In the comparative example 1, immediately after end of the etching processing, the tray 15 is carried out from the chamber 3 to the load lock chamber 10 (the stand-by time is zero minute). Meanwhile, in the comparative examples 2, 3, after a lapse of a preliminarily fixed stand-by time (two minutes in the comparative example 2 and five minutes in the comparative example 3) after the completion of the etching processing, the tray 15 is carried out from the chamber 3. During the stand-by time, the inside of the chamber 3 is in a vacuum ambient, and the heat transfer due to the atmosphere is not generated. Thus, the tray 15 is cooled by the heat transfer with the tray supporting surface 28 of the dielectric plate 23 (the tray 15 is placed in direct contact with the tray supporting surface 28 without putting the polyimide tape 91 inbetween).

In the experimental example 1, the tray 15 of the first embodiment (FIGS. 6A to 7C) was used. That is, the experimental example 1 is an example in which the substrate 2 is supported on the tray 15 in a point contact mode or in a line contact mode, but the cooling of the tray itself by providing the polyimide tape 91 between the tray 15 and the tray supporting surface 281s not executed. Meanwhile, in the experimental example 2, the tray 15 of the second embodiment (FIGS. 12 to 13B) was used. That is, the experimental example 2 is an example in which the cooling of the tray itself by providing the polyimide tape 91 between the tray 15 and the tray supporting surface 28 is executed, but the outer circumferential edge section of the substrate 2 is supported on the tray 15 in a surface contact mode (the substrate 2 is not supported in a point contact mode or in a line contact mode). In the experimental examples 1, 2, immediately after the completion of the etching processing, the tray 15 is carried out from the chamber 3 to the load lock chamber 10, and no stand-by time as in the comparative examples 2, 3 is provided (the stand-by time is zero minute).

The following conditions are applied to all the comparative examples 1 to 3 and the experimental examples 1, 2. A sapphire substrate (having thickness of about 520 μm) of 2 inches was used as the substrate 2. As shown in FIG. 4B, a tray containing seven substrates 2 was used as the tray 15. Major etching conditions are as follows. A Cl₂ gas was used as the etching gas, and a supply amount was 50 sccm. Pressure in the chamber 3 was 1.0 Pa, the high frequency power to be supplied to the ICP coil 5 was 400 W, and the bias power to be supplied to the substrate susceptor 9 was 300 W. The DC voltage to be applied to the electrostatic chuck electrode 40 was 1,000 V. Charging pressure of the heat transfer gas (He) to the space between the substrate 2 and the substrate placing surface 31 was 1,200 Pa. Temperatures of the top plate 4, a side wall of the chamber 3, and the dielectric plate 23 are respectively 100° C., 100° C., and 15° C.

Experimental results of the comparative examples 1 to 3 and the experimental examples 1, 2 are shown in the following tables 1 to 5.

TABLE 1
(Comparative Example 1: Stand-by time 0 minute)

| | Temperature of substrate (° C.) | | |
|---|---|---|---|
| | | Outer | |
| | Center | circumferential | Temperature |
| | section | edge section | of tray (° C.) |
| During | 76 | 76 | ≧254 |
| etching | | | |
| processing | | | |
| Load lock | 76 | 93 | — |
| chamber | | | |
| (before | | | |
| opening to | | | |
| atmosphere) | | | |
| Load lock | 93 | 130 | — |
| chamber | | | |
| (after | | | |
| opening to | | | |
| atmosphere) | | | |

TABLE 2
(Comparative Example 2: Stand-by time 2 minute)

| | Temperature of substrate (° C.) | | |
|---|---|---|---|
| | | Outer | |
| | Center | circumferential | Temperature |
| | section | edge section | of tray (° C.) |
| During | 76 | 76 | ≧254 |
| etching | | | |
| processing | | | |
| Load lock | 76 | 93 | — |
| chamber | | | |
| (before | | | |
| opening to | | | |
| atmosphere) | | | |
| Load lock | 82 | 120 | — |
| chamber | | | |
| (after | | | |
| opening to | | | |
| atmosphere) | | | |

TABLE 3
(Comparative Example 3: Stand-by time 5 minute)

| | Temperature of substrate (° C.) | | |
|---|---|---|---|
| | | Outer | |
| | Center | circumferential | Temperature |
| | section | edge section | of tray (° C.) |
| During | 76 | 76 | ≧254 |
| etching | | | |
| processing | | | |
| Load lock | 76 | 93 | — |
| chamber | | | |
| (before | | | |
| opening to | | | |
| atmosphere) | | | |
| Load lock | 82 | 98 | — |
| chamber | | | |
| (after | | | |
| opening to | | | |
| atmosphere) | | | |

TABLE 4
(Experimental Example 1: the substrate 2 is supported on the
tray 15 in a point contact or line contact mode)

| | Temperature of substrate (° C.) | | |
|---|---|---|---|
| | | Outer | |
| | Center | circumferential | Temperature |
| | section | edge section | of tray (° C.) |
| During | 76 | 76 | ≧254 |
| etching | | | |
| processing | | | |
| Load lock | 76 | 76 | — |
| chamber | | | |
| (before | | | |
| opening to | | | |
| atmosphere) | | | |
| Load lock | 82 | 87 | — |
| chamber | | | |
| (after | | | |
| opening to | | | |
| atmosphere) | | | |

TABLE 5
(Experimental Example 2: the tray 15 is placed on the tray
supporting surface 28 via the polyimide tape 91)

| | Temperature of substrate (° C.) | | |
|---|---|---|---|
| | | Outer | |
| | Center | circumferential | Temperature |
| | section | edge section | of tray (° C.) |
| During | 76 | 76 | ≦154 |
| etching | | | |
| processing | | | |
| Load lock | 76 | 82 | — |
| chamber | | | |
| (before | | | |
| opening to | | | |
| atmosphere) | | | |
| Load lock | 82 | 87 | — |
| chamber | | | |
| (after | | | |
| opening to | | | |
| atmosphere) | | | |

In the comparative example 1 (table 1), during the etching processing, both the center section and the outer circumferential edge section of the substrate 2 are maintained at 76° C. However, the temperature of the tray 15 is 254° C. or more. The center section is 76° C. and the outer circumferential edge section is 93° C. in the substrate 2 before the opening of the load lock chamber 10 to the atmosphere. Meanwhile, when the load lock chamber 10 is opened to the atmosphere, the center section is 93° C. and the outer circumferential edge section is 130° C. The temperature of the substrate 2 is considerably increased due to the heat transfer from the tray 15. Particularly, the temperature of the outer circumferential edge section of the substrate 2 is increased by about 40° C. between before and after the opening of the load lock chamber 10 to the atmosphere.

In the comparative example 2 (table 2), the temperatures of the substrate 2 and the tray 15 during the etching processing are the same as the comparative example 1. The center section is 76° C. and the outer circumferential edge section is 93° C. in the substrate 2 before the opening of the load lock chamber 10 to the atmosphere. Meanwhile, when the load lock chamber 10 is opened to the atmosphere, the center section is 82° C. and the outer circumferential edge section is 120° C. The temperature increase of the substrate 2 due to the heat transfer from the tray 15 is slightly reduced. This is because the temperature of the tray 15 is slightly decreased during the stand-by time of two minutes in the chamber 3. However, in the substrate 2 at the time of the opening of the load lock chamber 10 to the atmosphere, both the temperatures of the center section and the outer circumferential edge section remain high, and the substrate 2 is not sufficiently cooled.

In the comparative example 3 (table 3), the temperatures of the substrate 2 and the tray 15 during the etching processing are the same as the comparative example 1. The center section is 76° C. and the outer circumferential edge section is 93° C. in the substrate 2 before the opening of the load lock chamber 10 to the atmosphere. Meanwhile, when the load lock chamber 10 is opened to the atmosphere, the center section is 82° C. and the outer circumferential edge section is 98° C. The temperature increase of the outer circumferential edge section of the substrate 2 due to the heat transfer from the tray 15 is reduced effectively in comparison to the comparative examples 1, 3. This is because the stand-by time in the chamber 3 is set to be five minutes which are not less than double of the comparative example 2 (two minutes), and the temperature of the tray 15 is decreased during the stand-by time. However, when the stand-by time in the chamber 3 after the etching processing is set to be long as in this comparative example 3, the throughput is lowered. The temperature of the outer circumferential edge section of the substrate 2 at the time of the opening of the load lock chamber 10 to the atmosphere is 98° C., which is slightly higher than 82° C. of the temperature of the center section in the substrate 2.

In the experimental example 1 (table 4), the temperatures of the substrate 2 and the tray 15 during the etching processing are also the same as the comparative example 1. In the substrate 2 before the opening of the load lock chamber 10 to the atmosphere, the temperature of the center section is 76° C. which is the same as the comparative examples 1 to 3, but the temperature of the outer circumferential edge section is 76° C. which is lower than the comparative examples 1 to 3 (93° C.). In the substrate 2 after the opening of the load lock chamber 10 to the atmosphere, the temperature of the center section is 82° C. and the temperature of the outer circumferential edge section is 07° C. The temperature increase of the substrate 2 between before and after the opening of the load lock chamber 10 to the atmosphere is 6° C. in the center section and 11° C. in the outer circumferential edge section. In a case of the comparative examples 1, 2, the temperature increases of the outer circumferential edge section of the substrate 2 between before and after the opening of the load lock chamber 10 to the atmosphere are 37° C. and 27° C., respectively. In the experimental example 1, the temperature increase of the outer circumferential edge section of the substrate 2 between before and after the opening of the load lock chamber 10 to the atmosphere is effectively reduced. When comparing with the comparative example 3 in which the stand-by time of five minutes is provided, the temperature of the outer circumferential edge section of the substrate 2 after the opening of the load lock chamber 10 to the atmosphere is 98° C. in the comparative example 3 but 8° C. in the experimental example 1. From these points, it can be confirmed that the temperature increase of the outer circumferential edge section of the substrate 2 is effectively reduced by supporting the substrate 2 on the protruding sections 76A to 76C of the tray 15 in a point contact mode although the stand-by time is not provided.

In the experimental example 2 (table 5), during the etching processing, both the center section and the outer circumferential edge section of the substrate 2 are maintained at 76° C., which is the same as a case of the comparative examples 1 to 3. However, the temperature of the tray 15 during the etching processing is 254° C. or more in the comparative examples 1 to 3 but 154° C. or less in the experimental example 2. In this point, it can be confirmed that the tray 15 during the etching processing is effectively cooled by Attaching the polyimide tape 91 to the lower surface 15c of the substrate 15 by the vacuum adhesion. The temperature of the substrate 2 before the opening of the load lock chamber 10 to the atmosphere is 76° C. in the center section and 82° C. in the outer circumferential edge section. Meanwhile, the temperature of the substrate 2 after the opening of the load lock chamber 10 to the atmosphere is 82° C. in the center section and the 87° C. in the outer circumferential edge section. The temperature increase of the substrate 2 between before and after the opening of the load lock chamber 10 to the atmosphere is 6° C. in the center section and 5° C. in the outer circumferential edge section. The temperature increase is considerably reduced in comparison to the comparative example 1 (27° C.) and the comparative example 2 (37° C.). When comparing with the comparative example 3 in which the stand-by time of five minutes is provided, the temperature of the outer circumferential edge section of the substrate 2 after the opening of the load lock chamber 10 to the atmosphere is 98° C. in the comparative example 3 but 87° C. in the experimental example 2. From these points, it can be confirmed that the temperature increase of the outer circumferential edge section of the substrate 2 is effectively reduced by decreasing the temperature of the tray 15 during the etching processing by attaching the polyimide tape 91 by the vacuum adhesion although the stand-by time is not provided.

The present invention is described with the example of the ICP type dry etching processing apparatus. However, the present invention can be applied to other plasma processing apparatuses such as a parallel plate type RIE (reactive ion) type dry etching apparatus, and a plasma processing apparatus for plasma CVD.

1. A plasma processing apparatus, comprising:
a chamber capable of being decompressed;
a plasma generation source for generating plasma in the chamber;
a tray in which a substrate containing hole containing a substrate is formed so as to pass through in the thickness direction;
a substrate supporting section provided with an annular section protruding from the side of a lower surface of the tray in a hole wall of the substrate containing hole, and a plurality of substrate contact sections formed in at least one of the hole wall and an upper surface of the annular section, the substrate contact sections supporting in contact with three or more plural points of an outer circumferential edge section on the side of a lower surface of the substrate contained in the substrate containing hole, the three or more plural points being spaced from each other in the circumferential direction;
a dielectric member provided in the chamber, the dielectric member being provided with a tray supporting surface supporting the lower surface of the tray containing the substrate to be carried into the chamber, and a substrate placing section protruding upward from the tray supporting surface, the substrate placing section being inserted into the substrate containing hole from the side of the lower surface of the tray, the substrate placing section having a substrate placing surface serving as an upper end surface thereof on which the lower surface of the substrate is placed;
an electrostatic chuck electrode at least partly built in the substrate placing section, the electrostatic chuck electrode for electrostatically attracting the substrate onto the substrate placing surface;
a DC voltage application mechanism for applying DC voltage to the electrostatic chuck electrode; and a heat transfer gas supply mechanism for supplying a heat transfer gas to a space between the substrate and the substrate placing surface.

2. The plasma processing apparatus according to claim 1, wherein the substrate contact sections of the substrate supporting section are protruding sections formed on the upper surface of the annular section.

3. The plasma processing apparatus according to claim 1, wherein the substrate contact sections of the substrate supporting section are protruding sections formed on the hole wall.

4. The plasma processing apparatus according to claim 1, wherein the substrate contact sections of the substrate supporting section are protruding sections extending over the upper surface of the annular section and the hole wall.

5. The plasma processing apparatus according to claim 1, wherein a heat transfer material layer is formed on at least one of the lower surface of the tray and the tray supporting surface.

6. A plasma processing apparatus, comprising:
a chamber capable of being decompressed; a plasma generation source for generating plasma in the chamber;
a tray in which a substrate containing hole containing a substrate is formed so as to pass through in the thickness direction, and in which a hole wall of the substrate containing hole is inclined by a first inclination angle relative to the horizontal direction toward center of the substrate containing hole;
a substrate supporting section provided with an annular section protruding from the side of a lower surface of the tray in the hole wall, the annular section having a substrate contact section serving as an upper surface inclined by a second inclination angle which is smaller than the first inclination angle relative to the horizontal direction toward the center of the substrate containing hole, the substrate contact section supporting an outer circumferential edge section of the substrate contained in the substrate containing hole;
a dielectric member provided in the chamber, the dielectric member being provided with a tray supporting surface supporting the lower surface of the tray containing the substrate to be carried into the chamber, and a substrate placing section protruding upward from the tray supporting surface, the substrate placing section being inserted into the substrate containing hole from the side of the lower surface of the tray, the substrate placing section having a substrate placing surface serving as an upper end surface thereof on which the lower surface of the substrate is placed; an electrostatic chuck electrode at least partly built in the substrate placing section, the electrostatic chuck electrode for electrostatically attracting the substrate onto the substrate placing surface;
a DC voltage application mechanism for applying DC voltage to the electrostatic chuck electrode; and
a heat transfer gas supply mechanism for supplying a heat transfer gas to a space between the substrate and the substrate placing surface.

7. The plasma processing apparatus according to claim 6, wherein a heat transfer material layer is formed on at least one of the lower surface of the tray and the tray supporting surface.

8. A plasma processing apparatus, comprising:
a chamber capable of being decompressed;
a plasma generation source for generating plasma in the chamber; a tray in which a substrate containing hole containing a substrate is formed so as to pass through in the thickness direction; a substrate supporting section formed in a hole wall of the substrate containing hole, the substrate supporting section supporting an outer circumferential edge section of the substrate contained in the substrate containing hole;
a dielectric member provided in the chamber, the dielectric member being provided with a tray supporting surface supporting a lower surface of the tray containing the substrate to be carried into the chamber, and a substrate placing section protruding upward from the tray supporting surface, the substrate placing section being inserted into the substrate containing hole from the side of the lower surface of the tray, the substrate placing section having a substrate placing surface serving as an upper end surface thereof on which the lower surface of the substrate is placed;
a heat transfer material layer formed at least one of the lower surface of the tray and the tray supporting surface; an electrostatic chuck electrode at least partly built in the substrate placing section, the electrostatic chuck electrode for electrostatically attracting the substrate onto the substrate placing surface;
a DC voltage application mechanism for applying DC voltage to the electrostatic chuck electrode; and a heat transfer gas supply mechanism for supplying a heat transfer gas to a space between the substrate and the substrate placing surface.

9. A plasma processing method comprising:
putting a tape base material having an insulating property between a tray supporting surface of a dielectric member of a substrate susceptor and a lower surface of a tray containing a substrate in a substrate containing hole, and placing the tray on the tray supporting surface;
generating plasma and applying bias voltage to the substrate susceptor so as to generate a negative sheath potential on the tray placed on the tray supporting surface and polarize a potential in the tape base material; and
making the tray electrostatically attract itself onto the tray supporting surface of the dielectric member with the polarized tape base material.

10. The plasma processing apparatus according to claim 2, wherein a heat transfer material layer is formed on at least one of the lower surface of the tray and the tray supporting surface.

11. The plasma processing apparatus according to claim 3, wherein a heat transfer material layer is formed on at least one of the lower surface of the tray and the tray supporting surface.

12. The plasma processing apparatus according to claim 4, wherein a heat transfer material layer is formed on at least one of the lower surface of the tray and the tray supporting surface.
